(19) United States
(12) Patent Application Publication
(10) Pub. No.: US 2021/0167363 A1
(43) Pub. Date: Jun. 3, 2021

(54) Lead Storage Battery

(71) Applicant: The Furukawa Battery Co., Ltd., Yokohama-shi, Kanagawa (JP)

(72) Inventors: Satoshi Shibata, Iwaki-shi, Fukushima (JP); Shinya Suge, Iwaki-shi, Fukushima (JP); Hiroya Kaido, Iwaki-shi, Fukushima (JP)

(21) Appl. No.: 17/253,084

(22) PCT Filed: Aug. 1, 2019
(86) PCT No.: PCT/JP2019/030263

§ 371 Date: Dec. 16, 2020

(30) Foreign Application Priority Data
Sep. 27, 2018 (JP) 2018-182541
Sep. 27, 2018 (JP) 2018-182542
Sep. 27, 2018 (JP) 2018-182543

(51) Int. Cl. H01M 4/14; H01M 10/12; H01M 4/56; H01M 4/73; G01R 31/392

(52) U.S. Cl. CPC H01M 4/14; H01M 10/12; H01M 2004/021; H01M 4/73; G01R 31/392; H01M 4/56

(57) ABSTRACT

A lead acid battery is described that makes it possible to suppress an increase in internal resistance and to accurately determine the state of charge or the state of degradation by a method of measuring the internal resistance. The lead acid battery includes an electrode plate group in which a plurality of positive electrode plates having a positive active material containing lead dioxide and a plurality of negative electrode plates having a negative active material containing metallic lead are alternately stacked with separators interposed therebetween. The electrode plate group is immersed in an electrolyte. The flatness of the positive electrode plates after chemical conversion is equal to or less than 4.0 mm

### TECHNICAL FIELD

The present invention relates to a lead acid battery.

### BACKGROUND

Vehicles equipped with a charge control system or a stop-start system (hereinafter, these vehicles may also be referred to as “charge control vehicles” or “stop-start vehicles”) for the purpose of improving fuel economy and reducing exhaust gas have become mainstream in the car market in recent years. In these vehicles, the state of charge or the state of degradation of a lead acid battery is determined on the vehicle side, and based on its results, the charge/discharge of the lead acid battery or the stop-start of an engine is controlled. However, when the charge control system or the stop-start system is used, a large load is applied to the lead acid battery so that the life of the lead acid battery tends to be shortened. For example, because the charge and discharge of the lead acid battery are frequently repeated in both systems, there is a possibility that softening or falling-off of an active material occurs, resulting in early occurrence of a decrease in capacity. Further, because the state of charge of the lead acid battery tends to be reduced in the stop-start vehicle, when the charge acceptance performance of the lead acid battery is insufficient, there is a possibility that sulfation proceeds in which passive lead sulfate is accumulated on the surface of an electrode plate, resulting in an increase in internal resistance and early occurrence of a decrease in capacity.

Under these circumstances, the accuracy in determining the state of charge or the state of degradation is required for the lead acid battery for use in the charge control vehicle or the stop-start vehicle, in addition to the high durability and charge acceptance performance. As a technique for determining the state of charge or the state of degradation of the lead acid battery, there is known a method of measuring the internal resistance of the lead acid battery. However, because there are cases where the internal resistance of the lead acid battery is increased due to various factors other than the state of charge or the state of degradation, it is not easy to accurately determine the state of charge or the state of degradation.

### BRIEF SUMMARY

It is an object of the present invention to provide a lead acid battery that makes it possible to suppress an increase in internal resistance and to accurately determine the state of charge or the state of degradation by a method of measuring the internal resistance.

A lead acid battery according to one aspect of the present invention includes an electrode plate group in which a plurality of positive electrode plates having a positive active material containing lead dioxide and a plurality of negative electrode plates having a negative active material containing metallic lead are alternately stacked with separators interposed therebetween, wherein the electrode plate group is immersed in an electrolyte, and the flatness of the positive electrode plate after chemical conversion is equal to or less than 4.0 mm.

### BRIEF DESCRIPTION OF THE DRAWINGS

FIG. 1 is a partial sectional view for explaining the structure of a lead acid battery according to an embodiment of the present invention.

FIG. 2 is a diagram for explaining a method of measuring the flatness of an electrode plate.

FIG. 3 is a diagram of a positive electrode plate schematically illustrating the occurrence of curvature due to the difference between the thick coating degrees of a positive active material.

FIG. 4 is a sectional view for explaining the thick coating degree ratio between both plate surfaces of the positive electrode plate.

### DETAILED DESCRIPTION

An embodiment of the present invention will be described. The embodiment described below shows one example of the present invention, and the present invention is not limited to this embodiment. Various modifications or improvements can be added to this embodiment, and modes added with such modifications or improvements can also be included in the present invention.

As a result of intensive studies by the present inventors, new knowledge has been found about an increase in the internal resistance of a lead acid battery, which will be described in detail below.

In a lead acid battery, an electrode plate group in which a plurality of positive electrode plates and a plurality of negative electrode plates are alternately stacked with separators interposed therebetween is housed in a battery case in a state of being applied with a predetermined group pressure. In this case, because diffusion flow paths for an electrolyte necessary for charge/discharge reactions and discharge flow paths for gas are required between the electrode plates of the electrode plate group, a common technique is to interpose, between the electrode plates, ribbed separators provided with ribs on their base surfaces, thereby ensuring gaps serving as the diffusion flow paths for the electrolyte and the discharge flow paths for the gas.

However, even when such ribbed separators were used, there were cases where the internal resistance was increased and kept high and was hard to decrease. As a result of investigation by the present inventors of such a lead acid battery with the internal resistance kept high, it has been found that the electrode plates forming the electrode plate group are curved and that bubbles of gas are caught at edge portions of the curved electrode plates and thus are in a state of adhering to the electrode plates. Then, it has been found that, as a result of the adhesion of the bubbles of the gas to the electrode plates, the gas is trapped and stays in the electrode plate group, leading to a decrease in the contact area between an active material and the electrolyte (i.e. the area of portions where reactions occur) so that the internal resistance of the lead acid battery is increased.

It has also been found that because the distance between the adjacent electrode plates is reduced due to the curvature, the gas tends to be trapped between the electrode plates and thus is hard to exit to the outside of the electrode plate group.

Further, it has also been found that there is present the lead acid battery in which the internal resistance is not kept high even when the electrode plates are curved. From this fact, it has been found that there are cases where gas is hard to stay in the electrode plate group depending on the magnitude or shape of the curvature of the electrode plates.

By the studies of the present inventors, the cause for the curvature of the electrode plate has been found to be as follows. When forming an active material layer made of an active material on the surface of a substrate to produce an electrode plate, it is attempted to form active material layers of the same thickness respectively on both plate surfaces of the substrate. However, it is not easy to form the active material layers of the same thickness on both plate surfaces, and there are cases where active material layers of different thicknesses are formed. For example, in an example of FIG. 3, the thickness of an active material layer 102B formed on a plate surface 101b of a substrate 101 of an electrode plate 100 on the left side is greater than the thickness of an active material layer 102A formed on a plate surface 101a on the right side.

When the thicknesses of the active material layers 102A, 102B formed on both plate surfaces 101a, 101b of the substrate 101 differ from each other in this way, the electrode plate 100 is curved and deformed to a generally bowl shape due to chemical conversion as illustrated in FIG. 3. Further, as illustrated in FIG. 3, the electrode plate 100 is curved so that the plate surface 101b with the active material layer 102B having the greater thickness becomes a convex surface, and that the plate surface 101a with the active material layer 102A having the smaller thickness becomes a concave surface.

From the results of the studies described above, the present inventors have found that if the curvature of the electrode plate is prevented, it is possible to obtain a lead acid battery that makes it possible to suppress an increase in internal resistance due to chemical conversion, charge and discharge, or the like and to accurately determine the state of charge or the state of degradation by a method of measuring the internal resistance, and have completed the present invention.

Specifically, a lead acid battery according to an embodiment of the present invention includes an electrode plate group in which a plurality of positive electrode plates having a positive active material containing lead dioxide and a plurality of negative electrode plates having a negative active material containing metallic lead are alternately stacked with separators interposed therebetween, wherein the electrode plate group is immersed in an electrolyte and the flatness of the positive electrode plates after chemical conversion is equal to or less than 4.0 mm. Preferably, the flatness of each of all the positive electrode plates in the electrode plate group is equal to or less than 4.0 mm.

In comparison between the positive electrode plate and the negative electrode plate, the positive electrode plate tends to be curved in the chemical conversion. In view of this, in order to achieve the object of the present invention, it is important to control the flatness of the positive electrode plate to be small.

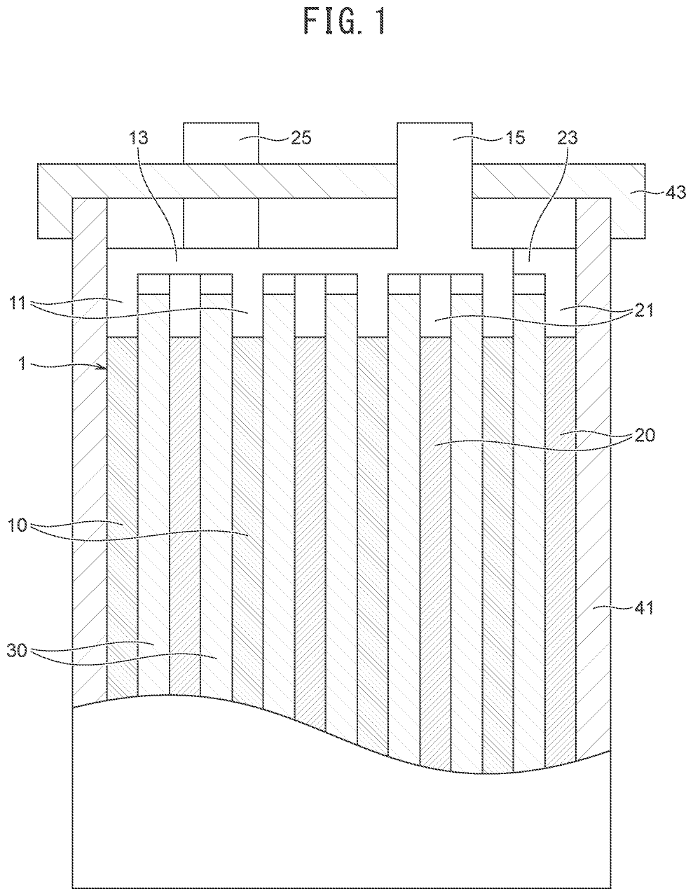

The structure of the lead acid battery according to the embodiment of the present invention will be described in further detail with reference to FIG. 1. The lead acid battery according to this embodiment includes an electrode plate group 1 in which a plurality of positive electrode plates 10 and a plurality of negative electrode plates 20 are alternately stacked with separators 30 interposed therebetween. The electrode plate group 1 is housed, along with a non-illustrated electrolyte, in a battery case 41 such that the stacking direction of the electrode plate group 1 is along the horizontal direction (i.e. plate surfaces of the positive electrode plates 10 and the negative electrode plates 20 are along the vertical direction), and the electrode plate group 1 is immersed in the electrolyte in the battery case 41.

The positive electrode plate 10 is produced in such a way that, for example, while filling a positive active material containing lead dioxide in openings of a plate-like grid made of a lead alloy, an active material layer made of the positive active material containing the lead dioxide is formed on both plate surfaces of the plate-like grid made of the lead alloy. The negative electrode plate 20 is produced in such a way that, for example, while filling a negative active material containing metallic lead in openings of a plate-like grid made of a lead alloy, an active material layer made of the negative active material containing the metallic lead is formed on both plate surfaces of the plate-like grid made of the lead alloy. The plate-like grids being substrates of the positive electrode plate 10 and the negative electrode plate 20 can be produced by a casting method, a punching method, or an expanding method. The separator 30 is, for example, a porous membrane member made of resin, glass, or the like.

Current collection lugs 11, 21 are respectively formed at upper end portions of the positive electrode plates 10 and the negative electrode plates 20. The current collection lugs 11 of the positive electrode plates 10 are joined by a positive electrode strap 13, and the current collection lugs 21 of the negative electrode plates 20 are joined together by a negative electrode strap 23. The positive electrode strap 13 is connected to one end of a positive electrode terminal 15, and the negative electrode strap 23 is connected to one end of a negative electrode terminal 25. The other end of the positive electrode terminal 15 and the other end of the negative electrode terminal 25 pass through a lid 43 closing an opening of the battery case 41 and are exposed to the outside of a case body of the lead acid battery formed by the battery case 41 and the lid 43.

In the lead acid battery according to this embodiment, having such a structure, the flatness of the positive electrode plate 10 after chemical conversion is made equal to or less than 4.0 mm. The smaller the numerical value of the flatness, the flatter the positive electrode plate 10, and bubbles of gas are hard to adhere to the surface of the positive electrode plate 10. When the flatness of the positive electrode plate 10 after chemical conversion is equal to or less than 4.0 mm, gas tends to be discharged to the outside of the electrode plate group 1, and therefore, it is possible to suppress an increase in the internal resistance of the lead acid battery and to accurately determine the state of charge or the state of degradation by a method of measuring the internal resistance.

A method to make the flatness of the positive electrode plate 10 after chemical conversion equal to or less than 4.0 mm is not particularly limited. The lead acid battery may be produced by a method that suppresses the curvature due to chemical conversion, or by correcting the positive electrode plate 10 curved due to chemical conversion so as to make the flatness equal to or less than 4.0 mm.

As described before, when the thicknesses of the active material layers formed on both plate surfaces of the positive electrode plate differ from each other, the curvature occurs on the positive electrode plate in chemical conversion. Accordingly, if the positive electrode plate formed with the active material layers of approximately the same thickness on both plate surfaces is subjected to chemical conversion, it is possible to suppress the curvature and to make the flatness equal to or less than 4.0 mm.

As a method to form the active material layers of the same thickness on both plate surfaces, the following two methods can be cited, for example. The first method is a method that, using a positive electrode plate formed with active material layers of different thicknesses on both plate surfaces, shaves the active material layer with a greater thickness to make its thickness equal to the thickness of the active material layer with a smaller thickness before stacking a negative electrode plate and a separator.

When it is attempted to simultaneously form active material layers on both plate surfaces of a positive electrode plate, it is difficult to form the active material layers of the same thickness. Therefore, the second method is a method that forms active material layers by filling a paste of a positive active material in openings of a plate-like grid on one side at a time, thereby forming the active material layers of the same thickness.

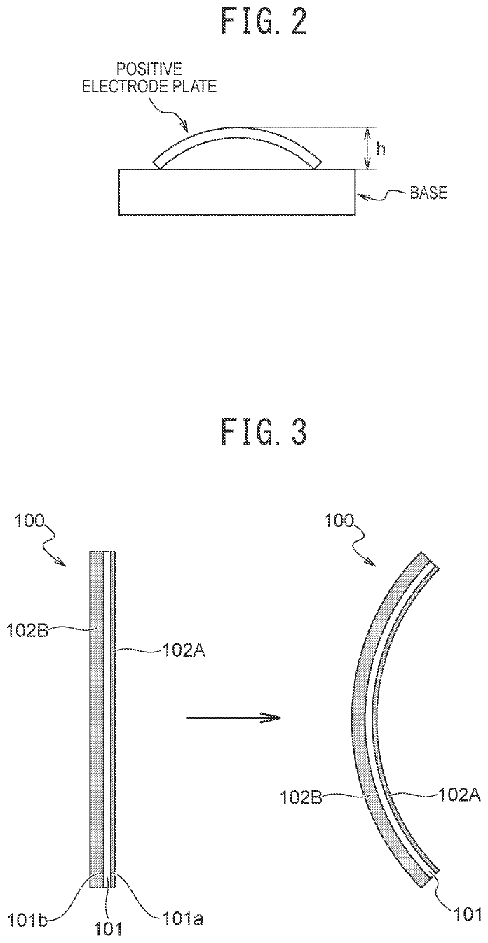

Note that when the flatness of the positive electrode plate 10 after chemical conversion is less than 0.5 mm, there is a possibility that although gas tends to be discharged to the outside of the electrode plate group 1, the group pressure applied to the electrode plate group 1 by the inner wall surfaces of the battery case 41 when the electrode plate group 1 is housed in the battery case 41 becomes insufficient. As a result, there are cases where softening or falling-off of the positive active material tends to occur, leading to a decrease in the performance or life of the lead acid battery. Therefore, the flatness of the positive electrode plate 10 after chemical conversion is preferably equal to or more than 0.5 mm. The flatness of the positive electrode plate can be measured by the method defined in JIS B0419:1991. Specifically, as illustrated in FIG. 2, a positive electrode plate is placed on a flat surface of a base such that plate surfaces of the positive electrode plate and the flat surface of the base are generally parallel to each other with a convex surface of the curved positive electrode plate facing upward, and the distance h between an apex of the convex surface of the curved positive electrode plate (a portion the farthest from the flat surface of the base) and the flat surface of the base is measured. Then, a value obtained by subtracting the thickness of the positive electrode plate from the distance h is defined as a flatness.

An electrode plate is curved also in a conventional lead acid battery, and a lead acid battery having an electrode plate with a flatness equal to or less than 4.0 mm has not been confirmed. For example, in a drawing of JP Pat. Pub. No. 2017-92001 A, while a flat electrode plate that is not curved is illustrated, the electrode plate is illustrated to be flat for convenience and actually is not flat, but curved. The knowledge that gas is trapped in the electrode plate group due to the curvature of the electrode plate to cause an increase in internal resistance is not known at all even by those skilled in the art.

As described above, the lead acid battery according to this embodiment is such that an increase in internal resistance due to chemical conversion, constant voltage charge, or the like is hard to occur and that a decrease in internal resistance after the charge is fast. Further, the lead acid battery according to this embodiment also has excellent durability and high charge acceptance performance (charge efficiency is high to allow short-time charge). Consequently, the lead acid battery according to this embodiment is suitable as a lead acid battery that is installed in a vehicle configured to perform charge control, such as a charge control vehicle or a stop-start vehicle, and that is mainly used in a partially charged state. The partially charged state is such that the state of charge is, for example, more than 70% and less than 100%.

The lead acid battery according to this embodiment can be used not only as a power supply for starting an internal combustion engine of a vehicle, but also as a power supply for driving an electric car, an electric forklift, an electric bus, an electric motorcycle, an electric scooter, a small electric moped, a golf cart, an electric locomotive, or the like. Further, the lead acid battery according to this embodiment can also be used as a lighting power supply or a standby power supply, or can also be used as a power storage device for electric energy generated by the photovoltaic power generation, the wind power generation, or the like.

In the lead acid battery according to this embodiment, the flatness of the negative electrode plate after chemical conversion is not particularly limited, and the flatness thereof may be small like the positive electrode plate after chemical conversion and may be, for example, equal to or less than 4.0 mm. The flatness of the positive electrode plate after chemical conversion and the flatness of the negative electrode plate after chemical conversion may be the same or may differ from each other, and preferably they differ from each other. For example, when the ratio of the flatness of the negative electrode plate to the flatness of the positive electrode plate is equal to or more than 50% and equal to or less than 80% in average in the electrode plate group, gas is hard to stay in the electrode plate group so that the gas tends to be discharged from the electrode plate group.

Hereinafter, the lead acid battery according to this embodiment will be described in further detail.

About Shape of Curvature of Positive Electrode Plate

As described before, there are cases where gas is hard to keep in the electrode plate group depending on the shape of the curvature of the positive electrode plate, and there is present the lead acid battery in which the internal resistance is not kept high even when the positive electrode plate after chemical conversion is curved. For example, in the case of the curvature shape such that the apex of the convex surface of the curved positive electrode plate is located at a portion below the center of the positive electrode plate in the vertical direction in the state where the positive electrode plate is disposed in the lead acid battery, it can be said that the curvature degree of a portion above the vertical direction center serving as an outlet for bubbles of gas is small, and therefore, the gas is hard to keep in the electrode plate group.

Specifically, when the curvature degree of a portion above the vertical direction center of the positive electrode plate, which is a portion serving as an outlet when bubbles of gas are discharged to the outside of the electrode plate group, is small, the gas is hard to keep in the electrode plate group and tends to be discharged, and therefore, an increase in the internal resistance of the lead acid battery is suppressed. Consequently, when the flatness of the portion above the vertical direction center in the positive electrode plate after chemical conversion is equal to or less than 4.0 mm, the effect of suppressing an increase in the internal resistance of the lead acid battery is exhibited.

About Density of Positive Active Material

The density of the positive active material included in the positive electrode plate is not particularly limited and is preferably equal to or more than 4.2 g/cm³ and equal to or less than 4.6 g/cm³ and more preferably equal to or more than 4.4 g/cm³ and equal to or less than 4.6 g/cm³. When the density of the positive active material is within the numerical value range described above, softening or falling-off of the positive active material is hard to occur, and therefore, the effect of improving the life of the lead acid battery is exhibited.

About Electrolyte

The composition of the electrolyte is not particularly limited, and an electrolyte used in a general lead acid battery can be used without any problem. On the other hand, in order to make the charge acceptance performance of the lead acid battery excellent, the electrolyte preferably contains aluminum, and the content of aluminum ions in the electrolyte is preferably equal to or more than 0.01 mol/L. However, when the content of aluminum ions in the electrolyte is high, gas is not easily discharged to the outside from the electrode plate group, and therefore, the content of aluminum ions in the electrolyte is preferably equal to or less than 0.3 mol/L.

The electrolyte may contain sodium ions. The content of sodium ions in the electrolyte can be equal to or more than 0.002 mol/L and equal to or less than 0.05 mol/L.

About Group Pressure Applied to Electrode Plate Group

As described before, the group pressure is applied to the electrode plate group by the inner wall surfaces of the battery case when the electrode plate group is housed in the battery case, and when the group pressure is insufficient, there are cases where softening or falling-off of the positive active material tends to occur, leading to a decrease in the performance or life of the lead acid battery. On the other hand, when the group pressure is too high, there is a possibility that gas stays in the positive active material to cause an increase in the internal resistance of the lead acid battery. Consequently, the group pressure applied to the electrode plate group is preferably equal to or less than 10 kPa.

About Lead Dioxide Contained in Positive Active Material

As lead dioxide, there are an orthorhombic α-phase (α-lead dioxide) and a tetragonal β-phase (β-lead dioxide). The ratio α/(α+β) between the mass α of the α-lead dioxide and the mass β of the β-lead dioxide contained in the positive active material is preferably equal to or more than 20% and equal to or less than 40%. With this configuration, stratification of the electrolyte is hard to occur, and therefore, the effect of improving the life of the lead acid battery is exhibited.

The α-lead dioxide is poor in porosity and thus small in specific surface area and therefore is small in discharge capacity, but the collapse of crystals proceeds quite slowly so that the softening rate is small. On the other hand, the β-lead dioxide is rich in porosity and thus large in specific surface area and therefore is large in discharge capacity, but the collapse of crystals proceeds fast so that the softening rate is large. Consequently, in order to achieve both the longer life and excellent discharge capacity of the lead acid battery, it is preferable that the α-lead dioxide and the β-lead dioxide be dispersed in the positive active material so that the ratio α/(α+β) between the mass α of the α-lead dioxide and the mass β of the β-lead dioxide contained in the positive active material becomes equal to or more than 20% and equal to or less than 40%.

When the ratio α/(α+β) between the mass α of the α-lead dioxide and the mass β of the β-lead dioxide is less than 20%, there is a possibility that the life of the lead acid battery becomes insufficient. On the other hand, when the ratio α/(α+β) between the mass a of the α-lead dioxide and the mass β of the β-lead dioxide is greater than 40%, there is a possibility that the capacity of the lead acid battery decreases.

About Pores Included in Positive Active Material

When the positive active material is porous, the average diameter of pores included in the positive active material is preferably equal to or more than 0.07 μm and equal to or less than 0.20 μm, and the porosity of the positive active material is preferably equal to or more than 30% and equal to or less than 50%.

When the average diameter of the pores included in the positive active material is less than 0.07 μm, there is a possibility that the utilization rate of the active material decreases. On the other hand, when the average diameter of the pores included in the positive active material is greater than 0.20 μm, there is a possibility that the internal resistance of the lead acid battery increases. Further, there is a possibility that softening of the positive active material tends to occur. A method to measure the average diameter of the pores included in the positive active material is not particularly limited, and, for example, it can be measured by a mercury press-in method.

When the porosity of the positive active material is less than 30%, there is a possibility that sulfuric acid is hard to permeate into the active material, resulting in a decrease in the utilization rate of the active material. On the other hand, when the porosity of the positive active material is greater than 50%, the density of the active material decreases, and therefore, there is a possibility that the life decreases.

A method to measure the porosity of the positive active material is not particularly limited, and, for example, it can be measured by the mercury press-in method.

About Surface Roughness Ra of Surface of Positive Electrode Plate

The surface roughness Ra of the surface of the positive electrode plate is not particularly limited and is preferably equal to or less than 0.20 mm. When the surface roughness Ra of the surface of the positive electrode plate is greater than 0.20 mm, gas tends to stay in cavities of irregularities of the surface of the positive electrode plate, and therefore, there is a possibility that the internal resistance increases. On the other hand, when the surface roughness Ra of the surface of the positive electrode plate is less than 0.05 mm, there is a possibility that the sedimentation rate of sulfuric acid produced on the surface of the positive electrode plate during the charge increases, resulting in that stratification of the electrolyte tends to occur.

About Distance between Adjacent Positive Electrode Plate and Negative Electrode Plate

The distance between the positive electrode plate and the negative electrode plate adjacent to each other in the electrode plate group is not particularly limited and is preferably equal to or more than 0.60 mm and equal to or less than 0.90 mm between any electrode plates.

When the distance between the adjacent positive and negative electrode plates is less than 0.60 mm, the amount of sulfuric acid present between the electrode plates decreases, and therefore, there is a possibility that the capacity of the lead acid battery decreases. On the other hand, when the distance between the adjacent positive and negative electrode plates is greater than 0.90 mm, the liquid resistance increases, and therefore, there is a possibility that the internal resistance of the lead acid battery increases. Further, there is a possibility that the internal resistance of the lead acid battery increases due to stay of gas.

While the distance between the adjacent positive and negative electrode plates is preferably equal to or more than 0.60 mm and equal to or less than 0.90 mm, this means that, in the present invention, the distance between both electrode plates is equal to or more than 0.60 mm and equal to or less than 0.90 mm at any portions on the plate surfaces of the electrode plates.

About Content of Iron Contained in Positive Active Material in Fully Charged State

The content of iron contained in the positive active material in a fully charged state (e.g. after chemical conversion) of the lead acid battery is not particularly limited and is preferably equal to or more than 3.5 ppm and equal to or less than 20.0 ppm. When iron is contained in the positive active material, gas tends to be produced on the positive electrode plate. Then, the produced gas rises in the electrolyte to stir the electrolyte so that stratification of the electrolyte is suppressed. When the content of iron contained in the positive active material in the fully charged state of the lead acid battery is within the range described above, the amount of gas produced on the positive electrode plate becomes an appropriate amount for stirring of the electrolyte so that the stratification of the electrolyte is further suppressed.

When the content of iron contained in the positive active material in the fully charged state of the lead acid battery is less than 3.5 ppm, because the amount of gas produced on the positive electrode plate decreases, the electrolyte is not sufficiently stirred, and therefore, there is a possibility that the stratification of the electrolyte tends to occur. In the production process of the lead acid battery, a number of production devices made of iron or stainless steel are used so that iron derived from these devices is mixed in. Therefore, it is difficult to make the content of iron, contained in the positive active material in the fully charged state of the lead acid battery, less than 3.5 ppm.

For example, a mixer for mixing a lead powder, being a material of a paste of the positive active material, with water and sulfuric acid, a hopper for supplying a material to a mixer, and so on are often formed of acid-resistant stainless steel. Therefore, in order to make the content of iron, contained in the positive active material in the fully charged state of the lead acid battery, less than 3.5 ppm, it is necessary that production devices for use in the production process of the lead acid battery be formed of non-ferrous metal, ceramic, or the like, or that a process of removing iron be added, thus leading to an increase in the production cost of the lead acid battery.

On the other hand, when the content of iron contained in the positive active material in the fully charged state of the lead acid battery is greater than 20.0 ppm, the electrolysis of the electrolyte is facilitated so that the amount of gas such as oxygen gas produced on the positive electrode plate increases, and therefore, there is a possibility that the liquid reduction of the electrolyte increases to shorten the life of the lead acid battery and that the internal resistance of the lead acid battery increases. Further, because the self-discharge is promoted, there is a possibility that the amount of voltage drop increases.

Iron present in the lead acid battery repeats the movement, i.e., moving to the positive electrode during the charge and moving to the negative electrode during the discharge, via the electrolyte (shuttle effect), and therefore, the gas production effect by iron is not limited to the positive electrode and occurs also at the negative electrode. Therefore, when the separator has a bag shape, even with the configuration in which either of the positive electrode plate and the negative electrode plate is housed in the bag-shaped separator, the same electrolyte stirring effect can be expected so that the degree of freedom of design of the lead acid battery is enhanced.

About Thick Coating Degree Ratio

As described before, the cause for the curvature of the electrode plate is the difference between the thicknesses of the active material layers formed on both plate surfaces of the electrode plate. Therefore, in order to make the flatness of the positive electrode plate after chemical conversion equal to or less than 4.0 mm, the ratio of the thickness of the active material layer of the positive active material formed on one of the plate surfaces of the positive electrode plate after chemical conversion to the thickness of the active material layer of the positive active material formed on the other one of the plate surfaces of the positive electrode plate after chemical conversion (hereinafter may also be referred to as “the thick coating degree ratio”) is preferably equal to or more than 0.67 and equal to or less than 1.33.

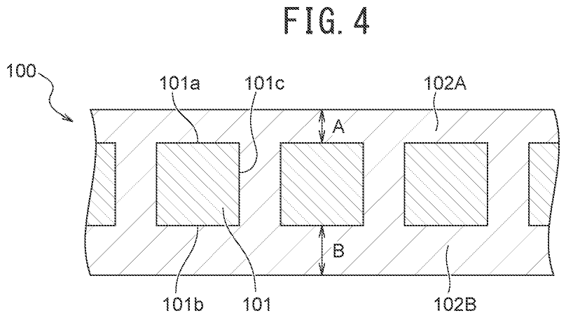

To give a description with reference to FIG. 4, a positive electrode plate 100 after chemical conversion is produced in such a way that while filling a positive active material containing lead dioxide in openings 101c of a positive electrode substrate 101 being a plate-like grid, positive active material layers 102A, 102B made of the positive active material containing the lead dioxide are respectively formed on both plate surfaces 101a, 101b of the positive electrode substrate 101. The ratio B/A of the thickness B of the positive active material layer 102B on the one plate surface 101b of the positive electrode plate 101 to the thickness A of the positive active material layer 102A on the other plate surface 101a of the positive electrode plate 101 is preferably equal to or more than 0.67 and equal to or less than 1.33.

In order to make the thick coating degree ratio between the active material layers of the positive active material after chemical conversion equal to or more than 0.67 and equal to or less than 1.33, the chemical conversion may be performed by making the thick coating degree ratio between the active material layers of the positive active material before chemical conversion equal to or more than 0.67 and equal to or less than 1.33. Even when the volume of the positive active material is changed in the process of the chemical conversion of the positive electrode plate, the thick coating degree ratio does not change before and after the chemical conversion as long as the chemical conversion conditions of both plate surfaces of the positive electrode plate are the same.

When the thick coating degree ratio of the positive electrode plate after chemical conversion is within the numerical value range described above, it is easy to make the flatness of the positive electrode plate after chemical conversion equal to or less than 4.0 mm. As a result, gas tends to be discharged to the outside of the electrode plate group, and therefore, it is possible to suppress an increase in the internal resistance of the lead acid battery and to accurately determine the state of charge or the state of degradation by a method of measuring the internal resistance.

The thickness of the active material layer of the positive active material is the distance between the surface of the positive electrode plate and the plate surface of the positive electrode substrate facing it, i.e. is the length of a portion of a virtual straight line, perpendicular to the surface of the positive electrode plate, from the surface of the positive electrode plate to the plate surface of the positive electrode substrate. The surface of the positive electrode plate is one flat plane in which step, bend, curvature, or the like is not substantially present on a macro-scale (about several ten μm to several mm). The thickness of the active material layer of the positive active material may be a value obtained by measuring the distance between the surface of the positive electrode plate and the plate surface of the positive electrode substrate at one portion, or an average value obtained by measuring the distance between the surface of the positive electrode plate and the plate surface of the positive electrode substrate at a plurality of portions.

For example, when the plate-like grid is used as the positive electrode substrate, because the surface of the positive electrode plate and the surfaces of vertical and horizontal grid bars forming the grid mesh of the plate-like grid face each other, the distance between the surface of the positive electrode plate and the surface of the grid bar may be measured, and the measured value may be defined as the thickness of the active material layer of the positive active material. Because the grid bars are arranged in a plurality in the plate-like grid, the distances between the surface of the positive electrode plate and the surfaces of the plurality of grid bars may be measured, and the average value of the measured values may be defined as the thickness of the active material layer of the positive active material.

The cross-sectional shape of the grid bar (the sectional shape of the grid bar when taken along a plane perpendicular to the longitudinal direction of the grid bar) of the plate-like grid is basically rectangular, and therefore, the surface of the positive electrode plate and the surface of the grid bar facing it are parallel to each other (see FIG. 4). However, in the case of the plate-like grid produced by the expanding method, there are cases where distortion or warping occurs on the plate-like grid in the production process. When the distortion or warping occurs on the plate-like grid, the surface of the grid bar is inclined or curved with respect to the surface of the positive electrode plate, and therefore, the surface of the positive electrode plate and the surface of the grid bar facing it are non-parallel to each other. In such a case, the distance between the surface of the positive electrode plate and the surface of the grid bar largely differs depending on a measuring portion, and therefore, the shortest distance between the surface of each of the grid bars and the surface of the positive electrode plate may be measured, and the average value of the measured values may be defined as the thickness of the active material layer of the positive active material.

The thick coating degree ratio in the present invention is the ratio of the thickness of the active material layer of the positive active material formed on one of the plate surfaces of the positive electrode plate after chemical conversion to the thickness of the active material layer of the positive active material formed on the other one of the plate surfaces of the positive electrode plate after chemical conversion, and can be calculated using as a denominator the thickness of the active material layer of the positive active material on either one of both plate surfaces of the positive electrode plate. For example, in the state where the positive electrode plate after chemical conversion is placed on the plane in a posture in which its both plate surfaces are perpendicular to the vertical direction with the current collection lug located on the upper right side, the ratio may be calculated using as a denominator the thickness of the active material layer of the positive active material on the upper one of both plate surfaces of the positive electrode plate and using as a numerator the thickness of the active material layer of the positive active material on the lower one of them, and may be defined as the thick coating degree ratio.

### EXAMPLES

Examples and Comparative Examples will be given below, and the present invention will be described more specifically.

(A) Study on Influence of Flatness of Positive Electrode Plate on Increase in Internal Resistance

First, plate-like grids made of a Pb-Ca-based or Pb-Ca-Sn-based lead alloy were cast, and a current collection lug was formed at a predetermined position of each of the plate-like grids. Then, a lead powder mainly composed of lead monoxide was kneaded with water and dilute sulfuric acid, and as needed, was further kneaded by mixing an additive, thereby producing a paste of a positive active material. Likewise, a lead powder mainly composed of lead monoxide was kneaded with water and dilute sulfuric acid, and as needed, was further kneaded by mixing an additive, thereby producing a paste of a negative active material.

Then, after filling the paste of the positive active material in the plate-like grids, maturation and drying were performed, and then chemical conversion was performed in a chemical conversion vessel, thereby obtaining ready-to-use (chemically converted) positive electrode plates each formed with active material layers of the positive active material containing lead dioxide on both plate surfaces of the electrode plate. Likewise, after filling the paste of the negative active material in the plate-like grids, maturation and drying were performed, and then chemical conversion was performed in a chemical conversion vessel, thereby obtaining ready-to-use (chemically converted) negative electrode plates each formed with active material layers of the negative active material containing metallic lead on both plate surfaces of the electrode plate. For the positive electrode plates, the flatness was measured by a later-described method.

The positive electrode plates and the negative electrode plates produced as described above were alternately stacked with separators, made of a porous synthetic resin, interposed therebetween, thereby producing an electrode plate group. The electrode plate group was housed in a battery case. The current collection lugs of the positive electrode plates were joined by a positive electrode strap, and the current collection lugs of the negative electrode plates were joined by a negative electrode strap. Then, the positive electrode strap was connected to one end of a positive electrode terminal, and the negative electrode strap was connected to one end of a negative electrode terminal.

Further, an opening of the battery case was closed with a lid. The positive electrode terminal and the negative electrode terminal were made to pass through the lid so that the other end of the positive electrode terminal and the other end of the negative electrode terminal were exposed to the outside of a lead acid battery. An electrolyte was injected through a liquid injection port formed in the lid and then the liquid injection port was sealed with a plug, thereby obtaining a lead acid battery.

The battery size was M-42 in which the number of the positive electrode plates and the number of the negative electrode plates forming the electrode plate group were respectively set to six and seven. The positive electrode plates and the negative electrode plates were produced by a continuous production method. The flatness of the positive electrode plate after chemical conversion was adjusted by changing the thick coating degree ratio between the active material layers of the positive active material formed on both plate surfaces of the positive electrode plate before chemical conversion.

The thickness of the separator was adjusted so that a predetermined group pressure was applied to the electrode plate group. The density of the positive active material included in the positive electrode plate was 4.4 g/cm³. The ratio α/(α+β) between the mass a of α-lead dioxide and the mass β of β-lead dioxide contained in the positive active material was 30%. The average diameter of pores included in the positive active material was 0.10 μm, and the porosity of the positive active material was 30%. The surface roughness Ra of the surface of the positive electrode plate was 0.10 mm. The distance between the adjacent positive and negative electrode plates was 0.60 mm. As the electrolyte, use was made of one containing aluminum sulfate in a concentration of 0.1 mol/L.

Then, after the initial charge was performed for the produced lead acid battery, aging was performed for 48 hours. Then, the internal resistance of the lead acid battery was measured. This internal resistance measured value was set as an “initial value”.

Subsequently, the constant voltage charge was performed for the lead acid battery in the fully charged state after the aging, and the internal resistance immediately after the end of the constant voltage charge was measured. This internal resistance measured value was set as a “value immediately after charge”. The conditions of the constant voltage charge were a maximum current of 100 A, a control voltage of 14.0 V, and a charge time of 10 minutes (this lead acid battery had a 5-hour rate capacity (rated capacity) of 32 Ah).

The lead acid battery was left still for an hour after the end of the constant voltage charge, and the internal resistance after being left still was measured. This internal resistance measured value was set as a “value after being left still”.

The flatness of the positive electrode plate was measured as follows. First, the thickness is measured at a plurality of portions of the positive electrode plate using a micrometer, and the average value of the measured values is set as the thickness of the positive electrode plate. Then, as illustrated in FIG. 2, the positive electrode plate is placed on the flat surface of the base such that the plate surfaces of the positive electrode plate and the flat surface of the base are generally parallel to each other with the convex surface of the curved positive electrode plate facing upward, and the distance h between the apex of the convex surface of the curved positive electrode plate and the flat surface of the base is measured using a height gauge. Then, a value obtained by subtracting the thickness of the positive electrode plate from the distance h is set as the flatness.

These results are shown in Table 1. The increase rate of the internal resistance was calculated using the initial value, the value immediately after charge, and the value after being left still, of the internal resistance. The increase rate of the value immediately after charge to the initial value was calculated by ([value immediately after charge]−[initial value])/[initial value], and the increase rate of the value after being left still to the initial value was calculated by ([value after being left still]−[initial value])/[initial value].

When a condition A that the increase rate of the value immediately after charge to the initial value is equal to or less than 10%, and a condition B that the increase rate of the value after being left still to the initial value is equal to or less than 5% or that the increase rate of the value after being left still is a value that is lower by 4% or more than the increase rate of the value immediately after charge are both satisfied, it is determined that the increase in internal resistance is significantly suppressed, and a mark ∘ is given in Table 1.

When only either one of the condition A and the condition B is satisfied, it is determined that while the increase in internal resistance is sufficiently suppressed, it cannot be said to be significantly suppressed, and a mark Δ is given in Table 1. When neither of the condition A and the condition B is satisfied, it is determined that the suppression of the increase in internal resistance is slightly insufficient or totally insufficient, and a mark × is given in Table 1.

TABLE 1

| | | | | | | Internal resistance | | |
|---|---|---|---|---|---|---|---|---|
| | | | | | | increase rate (%) | | |
| | | | Internal resistance (mΩ) | | | | Increase | |
| | | | | | Value | | rate of | |
| | | | | | after | Increase | value | |
| | | Group | | Value | being | rate of value | after | |
| | Flatness | pressure | Initial | immediately | left | immediately | being | |
| | (mm) | (kPa) | value | after charge | still | after charge | left still | Determination |
| Example 1 | 1.0 | 0 | 5.3 | 5.6 | 5.4 | 6 | 2 | ○ |
| Example 2 | 2.0 | 0 | 5.4 | 5.7 | 5.4 | 6 | 0 | ○ |
| Example 3 | 3.0 | 0 | 5.4 | 5.8 | 5.5 | 7 | 2 | ○ |
| Example 4 | 4.0 | 0 | 5.4 | 5.9 | 5.6 | 9 | 4 | ○ |
| Comparative | 5.0 | 0 | 5.5 | 6.4 | 6.3 | 16 | 15 | × |
| Example 1 | | | | | | | | |

From the results shown in Table 1, it is seen that the increase in internal resistance is significantly suppressed in Examples 1 to 4 in which the flatness of the positive electrode plate is equal to or less than 4.0 mm.

On the other hand, it is seen that the increase rate of the value immediately after charge to the initial value is high in Comparative Example 1 in which the flatness of the positive electrode plate is 5.0 mm. Further, because the increase rate of the value after being left still to the initial value is also high, it is seen that the decrease rate of the internal resistance is slow.

(B) Study on Influence of Group Pressure on Increase in Internal Resistance

Next, the influence of the group pressure applied to an electrode plate group was studied. The configuration of lead storage batteries, their production method, and their evaluation method were the same as those in the case of the study (A) described above except that the thickness of separators was adjusted so that predetermined group pressures were respectively applied to electrode plate groups. The evaluation results are collectively shown in Table 2.

From the evaluation results shown in Table 2, it is seen that even when the flatness of a positive electrode plate is equal to or less than 4.0 mm, when the group pressure is 20 kPa, the increase rate of the value after being left still to the initial value is high and thus the decrease rate of the internal resistance is slightly slow. This is considered to be because since the group pressure is high, gas is not easily discharged from the electrode plate group. From these results, it is seen that, in order to allow the internal resistance increased due to the constant voltage charge to return to the initial value fast, the group pressure applied to the electrode plate group is preferably set to be equal to or less than 10 kPa.

TABLE 2

| | | | | | | Internal resistance | | |
|---|---|---|---|---|---|---|---|---|
| | | | | | | increase rate (%) | | |
| | | | Internal resistance (mΩ) | | | | Increase | |
| | | | | | Value | | rate of | |
| | | | | | after | Increase | value | |
| | | Group | | Value | being | rate of value | after | |
| | Flatness | pressure | Initial | immediately | left | immediately | being | |
| | (mm) | (kPa) | value | after charge | still | after charge | left still | Determination |
| Example 2 | 2.0 | 0 | 5.4 | 5.7 | 5.4 | 6 | 0 | × |
| Example 5 | 2.0 | 10 | 5.4 | 5.7 | 5.5 | 6 | 2 | × |
| Example 6 | 2.0 | 20 | 5.4 | 5.7 | 5.7 | 6 | 6 | Δ |
| Example 4 | 4.0 | 0 | 5.4 | 5.9 | 5.6 | 9 | 4 | × |
| Example 7 | 4.0 | 10 | 5.4 | 5.9 | 5.6 | 9 | 4 | × |
| Example 8 | 4.0 | 20 | 5.4 | 5.8 | 5.8 | 7 | 7 | Δ |
| Comparative | 5.0 | 0 | 5.5 | 6.4 | 6.3 | 16 | 15 | × |
| Example 1 | | | | | | | | |
| Comparative | 5.0 | 10 | 5.5 | 6.4 | 6.4 | 16 | 16 | × |
| Example 2 | | | | | | | | |
| Comparative | 5.0 | 20 | 5.5 | 6.3 | 6.3 | 15 | 15 | × |
| Example 3 | | | | | | | | |

(C) Study on Influence of Density of Positive active material on Performance of Lead acid battery

The influence of the density of a positive active material was studied. Unless otherwise noted, the configuration of lead storage batteries and their production method were the same as those in the case of the study (A) described above except that the densities of positive active materials differed from each other. For the performance of the lead acid battery, the increase in internal resistance was evaluated like in the study (A) described above, and the stratification of an electrolyte and the battery life were also evaluated.

The stratification of the electrolyte and the battery life were evaluated by a 17.5% DOD life test defined in EN 50342-6:2015 of the European standard (EN standard). Specifically, the following operations (1), (2), and (3) were repeated in cycles, and it was determined that the life had been reached when the voltage became 10 V, and then, the number of the cycles performed until then was set as the battery life, and the difference in specific gravity between upper and lower portions of the electrolyte was measured.

(1) The state of charge (SOC) is adjusted to 50%.

(2) The charge and discharge at a discharge depth (DOD) of 17.5% are repeated 85 times.

(3) The battery is fully charged, and a 20 HR capacity test is performed. After the end of the capacity test, the full charge is performed again.

The evaluation results are shown in Tables 3 and 4. When a condition C that the battery life is equal to or more than 800 cycles, and a condition D that the stratification of the electrolyte (the difference in specific gravity between upper and lower portions of the electrolyte) is equal to or less than 0.03 are both satisfied, it is determined that the performance of the lead acid battery is significantly excellent, and a mark ∘ is given in Table 4. When only either one of the condition C and the condition D is satisfied, it is determined that while the performance of the lead acid battery is sufficiently excellent, it cannot be said to be significantly excellent, and a mark Δ is given in Table 4. When neither of the condition C nor the condition D is satisfied, it is determined that the performance of the lead acid battery is slightly insufficient or totally insufficient, and a mark × is given in Table 4.

From the evaluation results shown in Tables 3 and 4, it is seen that when the density of the positive active material is equal to or more than 4.2 g/cm³ and equal to or less than 4.6 g/cm³, the increase in internal resistance is significantly suppressed and the decrease rate of the internal resistance is fast. Further, it is seen that the battery life of the lead acid battery is excellent and that the stratification of the electrolyte is hard to occur.

TABLE 3

| | | | | | | Internal resistance | | |
|---|---|---|---|---|---|---|---|---|
| | | | | | | increase rate (%) | | |
| | | Density | Internal resistance (mΩ) | | | | Increase | |
| | | of | | | Value | | rate of | |
| | | positive | | | after | Increase | value | |
| | | active | | Value | being | rate of value | after | |
| | Flatness | material | Initial | immediately | left | immediately | being | |
| | (mm) | (g/cm³) | value | after charge | still | after charge | left still | Determination |
| Example 101 | 0.5 | 4.1 | 5.3 | 5.5 | 5.3 | 4 | 0 | ○ |
| Example 102 | | 4.2 | 5.3 | 5.5 | 5.3 | 4 | 0 | ○ |
| Example 103 | | 4.4 | 5.3 | 5.6 | 5.4 | 6 | 2 | ○ |
| Example 104 | | 4.6 | 5.3 | 5.6 | 5.5 | 6 | 4 | ○ |
| Example 105 | | 4.7 | 5.3 | 6.0 | 5.8 | 13 | 9 | Δ |
| Example 106 | 1.0 | 4.1 | 5.3 | 5.6 | 5.4 | 6 | 2 | ○ |
| Example 107 | | 4.2 | 5.3 | 5.5 | 5.4 | 4 | 2 | ○ |
| Example 108 | | 4.4 | 5.4 | 5.6 | 5.5 | 4 | 2 | ○ |
| Example 109 | | 4.6 | 5.4 | 5.7 | 5.6 | 6 | 4 | ○ |
| Example 110 | | 4.7 | 5.5 | 6.0 | 5.9 | 9 | 7 | Δ |
| Example 111 | 2.0 | 4.1 | 5.4 | 5.7 | 5.6 | 6 | 4 | ○ |
| Example 112 | | 4.2 | 5.4 | 5.7 | 5.5 | 6 | 2 | ○ |
| Example 113 | | 4.4 | 5.4 | 5.8 | 5.7 | 7 | 6 | ○ |
| Example 114 | | 4.6 | 5.5 | 5.9 | 5.8 | 7 | 5 | ○ |
| Example 115 | | 4.7 | 5.7 | 6.2 | 6.1 | 9 | 7 | Δ |
| Example 116 | 3.0 | 4.1 | 5.4 | 5.7 | 5.6 | 6 | 4 | ○ |
| Example 117 | | 4.2 | 5.4 | 5.8 | 5.6 | 7 | 4 | ○ |
| Example 118 | | 4.4 | 5.5 | 5.9 | 5.7 | 7 | 4 | ○ |
| Example 119 | | 4.6 | 5.6 | 6.0 | 5.8 | 7 | 4 | ○ |
| Example 120 | | 4.7 | 5.7 | 6.2 | 6.1 | 9 | 7 | Δ |
| Example 121 | 4.0 | 4.1 | 5.4 | 5.8 | 5.5 | 7 | 2 | ○ |
| Example 122 | | 4.2 | 5.4 | 5.9 | 5.6 | 9 | 4 | ○ |
| Example 123 | | 4.4 | 5.5 | 6.0 | 5.8 | 9 | 5 | ○ |
| Example 124 | | 4.6 | 5.6 | 6.0 | 5.9 | 7 | 5 | ○ |
| Example 125 | | 4.7 | 5.7 | 6.4 | 6.1 | 12 | 7 | Δ |
| Comparative | 5.0 | 4.1 | 5.6 | 6.3 | 6.2 | 13 | 11 | × |
| Example 101 | | | | | | | | |
| Comparative | | 4.2 | 5.6 | 6.4 | 6.3 | 14 | 13 | × |
| Example 102 | | | | | | | | |
| Comparative | | 4.4 | 5.7 | 6.5 | 6.5 | 14 | 14 | × |
| Example 103 | | | | | | | | |
| Comparative | | 4.6 | 5.7 | 6.5 | 6.5 | 14 | 14 | × |
| Example 104 | | | | | | | | |
| Comparative | | 4.7 | 5.7 | 6.7 | 6.6 | 18 | 16 | × |
| Example 105 | | | | | | | | |

TABLE 4

| | | Density of | | | |
|---|---|---|---|---|---|
| | | positive active | | Battery | |
| | Flatness | material | | life | Deter- |
| | (mm) | (g/cm³) | Stratification | (cycle) | mination |
| Example 101 | 0.5 | 4.1 | 0.01 | 480 | Δ |
| Example 102 | | 4.2 | 0.02 | 820 | ○ |
| Example 103 | | 4.4 | 0.02 | 980 | ○ |
| Example 104 | | 4.6 | 0.02 | 1040 | ○ |
| Example 105 | | 4.7 | 0.04 | 1110 | Δ |
| Example 106 | 1.0 | 4.1 | 0.01 | 470 | Δ |
| Example 107 | | 4.2 | 0.02 | 820 | ○ |
| Example 108 | | 4.4 | 0.03 | 950 | ○ |
| Example 109 | | 4.6 | 0.03 | 1000 | ○ |
| Example 110 | | 4.7 | 0.04 | 1090 | Δ |
| Example 111 | 2.0 | 4.1 | 0.01 | 460 | Δ |
| Example 112 | | 4.2 | 0.02 | 810 | ○ |
| Example 113 | | 4.4 | 0.02 | 930 | ○ |
| Example 114 | | 4.6 | 0.03 | 1010 | ○ |
| Example 115 | | 4.7 | 0.05 | 1070 | Δ |
| Example 116 | 3.0 | 4.1 | 0.01 | 460 | Δ |
| Example 117 | | 4.2 | 0.02 | 800 | ○ |
| Example 118 | | 4.4 | 0.03 | 920 | ○ |
| Example 119 | | 4.6 | 0.03 | 980 | ○ |
| Example 120 | | 4.7 | 0.05 | 1050 | Δ |
| Example 121 | 4.0 | 4.1 | 0.02 | 440 | Δ |
| Example 122 | | 4.2 | 0.03 | 800 | ○ |
| Example 123 | | 4.4 | 0.03 | 910 | ○ |
| Example 124 | | 4.6 | 0.03 | 930 | ○ |
| Example 125 | | 4.7 | 0.06 | 930 | Δ |
| Comparative | 5.0 | 4.1 | 0.06 | 340 | × |
| Example 101 | | | | | |
| Comparative | | 4.2 | 0.07 | 410 | × |
| Example 102 | | | | | |
| Comparative | | 4.4 | 0.07 | 600 | × |
| Example 103 | | | | | |
| Comparative | | 4.6 | 0.07 | 700 | × |
| Example 104 | | | | | |
| Comparative | | 4.7 | 0.08 | 790 | × |
| Example 105 | | | | | |

(D) Study on Influence of αβ Ratio of Lead Dioxide on Performance of Lead acid battery

The influence of the ratio α/(α+β) between the mass a of α-lead dioxide and the mass β of β-lead dioxide contained in a positive active material was studied. Unless otherwise noted, the configuration of lead storage batteries and their production method were the same as those in the case of the study (A) described above except that the αβ ratios of lead dioxides differed from each other. For the performance of the lead acid battery, the increase in internal resistance was evaluated like in the study (A) described above, and the stratification of an electrolyte and the battery life were also evaluated like in the study (C) described above.

The evaluation results are shown in Tables 5 and 6. From the evaluation results shown in Tables 5 and 6, it is seen that when the αβ ratio α/(α+β) of the lead dioxide is equal to or more than 20% and equal to or less than 40%, the increase in internal resistance is sufficiently suppressed and the decrease rate of the internal resistance is fast. Further, it is seen that the battery life of the lead acid battery is excellent and that the stratification of the electrolytes does on occur easily.

TABLE 5

| | | | | | | Internal resistance | | |
|---|---|---|---|---|---|---|---|---|
| | | | | | | increase rate (%) | | |
| | | | Internal resistance (mΩ) | | | | Increase | |
| | | | | | Value | | rate of | |
| | | | | | after | Increase | value | |
| | | αβ | | Value | being | rate of value | after | |
| | Flatness | ratio | Initial | immediately | left | immediately | being | |
| | (mm) | (%) | value | after charge | still | after charge | left still | Determination |
| Example 201 | 0.5 | 10 | 5.3 | 5.5 | 5.3 | 4 | 0 | ○ |
| Example 202 | | 20 | 5.3 | 5.5 | 5.3 | 4 | 0 | ○ |
| Example 203 | | 30 | 5.3 | 5.5 | 5.4 | 4 | 2 | ○ |
| Example 204 | | 40 | 5.3 | 5.7 | 5.5 | 8 | 4 | ○ |
| Example 205 | | 50 | 5.3 | 5.8 | 5.8 | 9 | 9 | Δ |
| Example 206 | 1.0 | 10 | 5.3 | 5.6 | 5.4 | 6 | 2 | ○ |
| Example 207 | | 20 | 5.3 | 5.6 | 5.4 | 6 | 2 | ○ |
| Example 208 | | 30 | 5.3 | 5.6 | 5.5 | 6 | 4 | ○ |
| Example 209 | | 40 | 5.4 | 5.7 | 5.6 | 6 | 4 | ○ |
| Example 210 | | 50 | 5.5 | 6.0 | 5.9 | 9 | 7 | Δ |
| Example 211 | 2.0 | 10 | 5.4 | 5.7 | 5.5 | 6 | 2 | ○ |
| Example 212 | | 20 | 5.4 | 5.7 | 5.5 | 6 | 2 | ○ |
| Example 213 | | 30 | 5.5 | 5.8 | 5.6 | 5 | 2 | ○ |
| Example 214 | | 40 | 5.5 | 5.8 | 5.7 | 5 | 4 | ○ |
| Example 215 | | 50 | 5.7 | 6.2 | 6.1 | 9 | 7 | Δ |
| Example 216 | 3.0 | 10 | 5.4 | 5.7 | 5.6 | 6 | 4 | ○ |
| Example 217 | | 20 | 5.4 | 5.8 | 5.5 | 7 | 2 | ○ |
| Example 218 | | 30 | 5.5 | 5.9 | 5.7 | 7 | 4 | ○ |
| Example 219 | | 40 | 5.6 | 5.9 | 5.8 | 5 | 4 | ○ |
| Example 220 | | 50 | 5.7 | 6.2 | 6.2 | 9 | 9 | Δ |
| Example 221 | 4.0 | 10 | 5.4 | 5.8 | 5.5 | 7 | 2 | ○ |
| Example 222 | | 20 | 5.4 | 5.9 | 5.6 | 9 | 4 | ○ |
| Example 223 | | 30 | 5.5 | 5.9 | 5.8 | 7 | 5 | ○ |
| Example 224 | | 40 | 5.6 | 6.0 | 5.9 | 7 | 5 | ○ |
| Example 225 | | 50 | 5.7 | 6.2 | 6.2 | 9 | 9 | Δ |
| Comparative | 5.0 | 10 | 5.5 | 6.4 | 6.2 | 16 | 13 | × |
| Example 201 | | | | | | | | |
| Comparative | | 20 | 5.5 | 6.4 | 6.3 | 16 | 15 | × |
| Example 202 | | | | | | | | |
| Comparative | | 30 | 5.5 | 6.5 | 6.4 | 18 | 16 | × |
| Example 203 | | | | | | | | |
| Comparative | | 40 | 5.5 | 6.5 | 6.4 | 18 | 16 | × |
| Example 204 | | | | | | | | |
| Comparative | | 50 | 5.6 | 6.7 | 6.6 | 20 | 18 | × |
| Example 205 | | | | | | | | |

TABLE 6

| | Flatness | αβ ratio | | Battery life | Deter- |
|---|---|---|---|---|---|
| | (mm) | (%) | Stratification | (cycle) | mination |
| Example 201 | 0.5 | 10 | 0.01 | 470 | Δ |
| Example 202 | | 20 | 0.02 | 830 | ○ |
| Example 203 | | 30 | 0.02 | 970 | ○ |
| Example 204 | | 40 | 0.03 | 1050 | ○ |
| Example 205 | | 50 | 0.04 | 1100 | Δ |
| Example 206 | 1.0 | 10 | 0.01 | 460 | Δ |
| Example 207 | | 20 | 0.02 | 820 | ○ |
| Example 208 | | 30 | 0.02 | 960 | ○ |
| Example 209 | | 40 | 0.03 | 1010 | ○ |
| Example 210 | | 50 | 0.04 | 1090 | Δ |
| Example 211 | 2.0 | 10 | 0.01 | 450 | Δ |
| Example 212 | | 20 | 0.02 | 810 | ○ |
| Example 213 | | 30 | 0.03 | 930 | ○ |
| Example 214 | | 40 | 0.03 | 1000 | ○ |
| Example 215 | | 50 | 0.05 | 1070 | Δ |
| Example 216 | 3.0 | 10 | 0.01 | 440 | Δ |
| Example 217 | | 20 | 0.02 | 790 | ○ |
| Example 218 | | 30 | 0.03 | 920 | ○ |
| Example 219 | | 40 | 0.03 | 990 | ○ |
| Example 220 | | 50 | 0.05 | 1050 | Δ |
| Example 221 | 4.0 | 10 | 0.01 | 430 | Δ |
| Example 222 | | 20 | 0.02 | 770 | ○ |
| Example 223 | | 30 | 0.03 | 900 | ○ |
| Example 224 | | 40 | 0.03 | 920 | ○ |
| Example 225 | | 50 | 0.06 | 900 | Δ |
| Comparative | 5.0 | 10 | 0.06 | 350 | × |
| Example 201 | | | | | |
| Comparative | | 20 | 0.06 | 400 | × |
| Example 202 | | | | | |
| Comparative | | 30 | 0.07 | 590 | × |
| Example 203 | | | | | |
| Comparative | | 40 | 0.07 | 710 | × |
| Example 204 | | | | | |
| Comparative | | 50 | 0.08 | 790 | × |
| Example 205 | | | | | |

(E) Study on Influence of Average Diameter of Pores Included in Positive Active Material and Porosity of Positive Active Material on Performance of Lead Acid Battery.

The influence of the average diameter of pores included in a positive active material and the porosity of the positive active material was studied. Unless otherwise noted, the configuration of lead storage batteries and their production method were the same as those in the case of the study (A) described above except that the average diameters of pores included in positive active materials or the porosities of positive active materials differed from each other. For the performance of the lead acid battery, the increase in internal resistance was evaluated like in the study (A) described above, and the utilization rate of the active material was also evaluated.

The utilization rate of the active material was obtained by measuring the discharge capacity after performing a 5-hour rate discharge test.

The evaluation results are shown in Tables 7, 8, 9, and 10. When a measured value of the discharge capacity is equal to or more than 32 Ah being the rated capacity of M-42, it is determined that the utilization rate is significantly excellent, and a mark ∘ is given in Tables 8 and 10. When the measured value of the discharge capacity is equal to or more than 30 Ah and less than 32 Ah, it is determined that while the utilization rate is sufficiently excellent, it cannot be said to be significantly excellent, and a mark Δ is given in Tables 8 and 10. When the measured value of the discharge capacity is less than 30 Ah, it is determined that the utilization rate is slightly insufficient or totally insufficient, and a mark × is given in Tables 8 and 10.

From the evaluation results shown in Tables 7, 8, 9, and 10, it is seen that when the average diameter of the pores included in the positive active material is equal to or more than 0.07 μm and equal to or less than 0.20 μm, or the porosity of the positive active material is equal to or more than 30% and equal to or less than 50%, the increase in internal resistance is significantly suppressed and the decrease rate of the internal resistance is fast. Further, it is seen that the utilization rate of the active material is significantly excellent.

TABLE 7

| | | | | | | Internal resistance | | |
|---|---|---|---|---|---|---|---|---|
| | | | | | | increase rate (%) | | |
| | | | Internal resistance (mΩ) | | | | Increase | |
| | | | | | Value | | rate of | |
| | | Average | | | after | Increase | value | |
| | | diameter | | Value | being | rate of value | after | |
| | Flatness | of pore | Initial | immediately | left | immediately | being | |
| | (mm) | (μm) | value | after charge | still | after charge | left still | Determination |
| Example 301 | 0.5 | 0.05 | 5.3 | 5.4 | 5.3 | 2 | 0 | ○ |
| Example 302 | | 0.10 | 5.3 | 5.4 | 5.3 | 2 | 0 | ○ |
| Example 303 | | 0.15 | 5.3 | 5.6 | 5.4 | 6 | 2 | ○ |
| Example 304 | | 0.20 | 5.3 | 5.6 | 5.5 | 6 | 4 | ○ |
| Example 305 | | 0.25 | 5.3 | 6.0 | 5.6 | 13 | 6 | Δ |
| Example 306 | 1.0 | 0.05 | 5.3 | 5.5 | 5.4 | 4 | 2 | ○ |
| Example 307 | | 0.10 | 5.3 | 5.5 | 5.4 | 4 | 2 | ○ |
| Example 308 | | 0.15 | 5.4 | 5.6 | 5.5 | 4 | 2 | ○ |
| Example 309 | | 0.20 | 5.4 | 5.7 | 5.6 | 6 | 4 | ○ |
| Example 310 | | 0.25 | 5.5 | 6.1 | 5.7 | 11 | 4 | Δ |
| Example 311 | 2.0 | 0.05 | 5.4 | 5.6 | 5.5 | 4 | 2 | ○ |
| Example 312 | | 0.10 | 5.4 | 5.6 | 5.5 | 4 | 2 | ○ |
| Example 313 | | 0.15 | 5.5 | 5.7 | 5.6 | 4 | 2 | ○ |
| Example 314 | | 0.20 | 5.5 | 5.8 | 5.7 | 5 | 4 | ○ |
| Example 315 | | 0.25 | 5.7 | 6.3 | 5.9 | 11 | 4 | Δ |
| Example 316 | 3.0 | 0.05 | 5.4 | 5.6 | 5.5 | 4 | 2 | ○ |
| Example 317 | | 0.10 | 5.4 | 5.8 | 5.6 | 7 | 4 | ○ |
| Example 318 | | 0.15 | 5.5 | 6.0 | 5.7 | 9 | 4 | ○ |
| Example 319 | | 0.20 | 5.6 | 6.1 | 5.9 | 9 | 5 | ○ |
| Example 320 | | 0.25 | 5.7 | 6.4 | 6.0 | 12 | 5 | Δ |
| Example 321 | 4.0 | 0.05 | 5.4 | 5.7 | 5.5 | 6 | 2 | ○ |
| Example 322 | | 0.10 | 5.4 | 5.7 | 5.5 | 6 | 2 | ○ |
| Example 323 | | 0.15 | 5.5 | 5.8 | 5.7 | 5 | 4 | ○ |
| Example 324 | | 0.20 | 5.6 | 6.0 | 5.9 | 7 | 5 | ○ |
| Example 325 | | 0.25 | 5.7 | 6.4 | 6.1 | 12 | 7 | Δ |
| Comparative | 5.0 | 0.05 | 5.5 | 6.4 | 6.2 | 16 | 13 | × |
| Example 301 | | | | | | | | |
| Comparative | | 0.10 | 5.5 | 6.4 | 6.3 | 16 | 15 | × |
| Example 302 | | | | | | | | |
| Comparative | | 0.15 | 5.5 | 6.5 | 6.4 | 18 | 16 | × |
| Example 303 | | | | | | | | |
| Comparative | | 0.20 | 5.5 | 6.5 | 6.5 | 18 | 18 | × |
| Example 304 | | | | | | | | |
| Comparative | | 0.25 | 5.6 | 6.7 | 6.6 | 20 | 18 | × |
| Example 305 | | | | | | | | |

TABLE 8

| | | Average | | |
|---|---|---|---|---|
| | Flatness | diameter of pore | 5 HR capacity | |
| | (mm) | (μm) | (Ah) | Determination |
| Example 301 | 0.5 | 0.05 | 30.0 | Δ |
| Example 302 | | 0.10 | 32.2 | ○ |
| Example 303 | | 0.15 | 32.5 | ○ |
| Example 304 | | 0.20 | 32.6 | ○ |
| Example 305 | | 0.25 | 33.0 | ○ |
| Example 306 | 1.0 | 0.05 | 31.0 | Δ |
| Example 307 | | 0.10 | 32.1 | ○ |
| Example 308 | | 0.15 | 32.4 | ○ |
| Example 309 | | 0.20 | 33.2 | ○ |
| Example 310 | | 0.25 | 33.5 | ○ |
| Example 311 | 2.0 | 0.05 | 30.7 | Δ |
| Example 312 | | 0.10 | 32.5 | ○ |
| Example 313 | | 0.15 | 32.6 | ○ |
| Example 314 | | 0.20 | 33.0 | ○ |
| Example 315 | | 0.25 | 33.5 | ○ |
| Example 316 | 3.0 | 0.05 | 30.2 | Δ |
| Example 317 | | 0.10 | 32.3 | ○ |
| Example 318 | | 0.15 | 32.5 | ○ |
| Example 319 | | 0.20 | 32.9 | ○ |
| Example 320 | | 0.25 | 33.2 | ○ |
| Example 321 | 4.0 | 0.05 | 30.0 | Δ |
| Example 322 | | 0.10 | 32.2 | ○ |
| Example 323 | | 0.15 | 32.5 | ○ |
| Example 324 | | 0.20 | 32.7 | ○ |
| Example 325 | | 0.25 | 33.0 | ○ |
| Comparative | 5.0 | 0.05 | 27.3 | × |
| Example 301 | | | | |
| Comparative | | 0.10 | 28.0 | × |
| Example 302 | | | | |
| Comparative | | 0.15 | 28.3 | × |
| Example 303 | | | | |
| Comparative | | 0.20 | 28.5 | × |
| Example 304 | | | | |
| Comparative | | 0.25 | 28.9 | × |
| Example 305 | | | | |

TABLE 9

| | | | | | | Internal resistance | | |
|---|---|---|---|---|---|---|---|---|
| | | | | | | increase rate (%) | | |
| | | | Internal resistance (mΩ) | | | | Increase | |
| | | | | | Value | | rate of | |
| | | | | | after | Increase | value | |
| | | | | Value | being | rate of value | after | |
| | Flatness | Porosity | Initial | immediately | left | immediately | being | |
| | (mm) | (%) | value | after charge | still | after charge | left still | Determination |
| Example 401 | 0.5 | 20 | 5.3 | 5.6 | 5.6 | 6 | 6 | Δ |
| Example 402 | | 30 | 5.3 | 5.5 | 5.5 | 4 | 4 | ○ |
| Example 403 | | 40 | 5.3 | 5.6 | 5.5 | 6 | 4 | ○ |
| Example 404 | | 50 | 5.3 | 5.7 | 5.4 | 8 | 2 | ○ |
| Example 405 | | 60 | 5.3 | 6.0 | 5.6 | 13 | 6 | Δ |
| Example 406 | 1.0 | 20 | 5.3 | 5.6 | 5.6 | 6 | 6 | Δ |
| Example 407 | | 30 | 5.3 | 5.6 | 5.4 | 6 | 2 | ○ |
| Example 408 | | 40 | 5.4 | 5.7 | 5.6 | 6 | 4 | ○ |
| Example 409 | | 50 | 5.5 | 5.8 | 5.6 | 5 | 2 | ○ |
| Example 410 | | 60 | 5.5 | 6.1 | 5.7 | 11 | 4 | Δ |
| Example 411 | 2.0 | 20 | 5.4 | 5.7 | 5.7 | 6 | 6 | Δ |
| Example 412 | | 30 | 5.5 | 5.7 | 5.5 | 4 | 0 | ○ |
| Example 413 | | 40 | 5.5 | 5.8 | 5.6 | 5 | 2 | ○ |
| Example 414 | | 50 | 5.5 | 5.8 | 5.7 | 5 | 4 | ○ |
| Example 415 | | 60 | 5.7 | 6.3 | 5.9 | 11 | 4 | Δ |
| Example 416 | 3.0 | 20 | 5.4 | 5.8 | 5.7 | 7 | 6 | Δ |
| Example 417 | | 30 | 5.5 | 5.8 | 5.6 | 5 | 2 | ○ |
| Example 418 | | 40 | 5.5 | 6.0 | 5.8 | 9 | 5 | ○ |
| Example 419 | | 50 | 5.6 | 6.1 | 5.9 | 9 | 5 | ○ |
| Example 420 | | 60 | 5.7 | 6.4 | 6.0 | 12 | 5 | Δ |
| Example 421 | 4.0 | 20 | 5.4 | 5.8 | 5.7 | 7 | 6 | Δ |
| Example 422 | | 30 | 5.4 | 5.8 | 5.6 | 7 | 4 | ○ |
| Example 423 | | 40 | 5.5 | 5.9 | 5.7 | 7 | 4 | ○ |
| Example 424 | | 50 | 5.6 | 6.0 | 5.9 | 7 | 5 | ○ |
| Example 425 | | 60 | 5.7 | 6.4 | 6.1 | 12 | 7 | Δ |
| Comparative | 5.0 | 20 | 5.5 | 6.4 | 6.4 | 16 | 16 | × |
| Example 401 | | | | | | | | |
| Comparative | | 30 | 5.5 | 6.4 | 6.4 | 16 | 16 | × |
| Example 402 | | | | | | | | |
| Comparative | | 40 | 5.5 | 6.6 | 6.4 | 20 | 16 | × |
| Example 403 | | | | | | | | |
| Comparative | | 50 | 5.5 | 6.7 | 6.4 | 22 | 16 | × |
| Example 404 | | | | | | | | |
| Comparative | | 60 | 5.6 | 6.8 | 6.3 | 21 | 13 | × |
| Example 405 | | | | | | | | |

TABLE 10

| | Flatness | Porosity | 5 HR capacity | |
|---|---|---|---|---|
| | (mm) | (%) | (Ah) | Determination |
| Example 401 | 0.5 | 20 | 30.4 | Δ |
| Example 402 | | 30 | 32.3 | ○ |
| Example 403 | | 40 | 32.4 | ○ |
| Example 404 | | 50 | 32.7 | ○ |
| Example 405 | | 60 | 33.3 | ○ |
| Example 406 | 1.0 | 20 | 30.9 | Δ |
| Example 407 | | 30 | 32.3 | ○ |
| Example 408 | | 40 | 32.6 | ○ |
| Example 409 | | 50 | 33.1 | ○ |
| Example 410 | | 60 | 33.6 | ○ |
| Example 411 | 2.0 | 20 | 30.5 | Δ |
| Example 412 | | 30 | 32.6 | ○ |
| Example 413 | | 40 | 32.6 | ○ |
| Example 414 | | 50 | 32.9 | ○ |
| Example 415 | | 60 | 33.4 | ○ |
| Example 416 | 3.0 | 20 | 30.3 | Δ |
| Example 417 | | 30 | 32.3 | ○ |
| Example 418 | | 40 | 32.6 | ○ |
| Example 419 | | 50 | 33.0 | ○ |
| Example 420 | | 60 | 33.4 | ○ |
| Example 421 | 4.0 | 20 | 30.0 | Δ |
| Example 422 | | 30 | 32.1 | ○ |
| Example 423 | | 40 | 32.4 | ○ |
| Example 424 | | 50 | 32.7 | ○ |
| Example 425 | | 60 | 33.1 | ○ |
| Comparative | 5.0 | 20 | 27.9 | × |
| Example 401 | | | | |
| Comparative | | 30 | 28.8 | × |
| Example 402 | | | | |
| Comparative | | 40 | 28.9 | × |
| Example 403 | | | | |
| Comparative | | 50 | 29.5 | × |
| Example 404 | | | | |
| Comparative | | 60 | 29.9 | × |
| Example 405 | | | | |

F) Study on Influence of Surface Roughness Ra of Surface of Positive Electrode Plate on Increase in Internal Resistance

The influence of the surface roughness Ra of the surface of a positive electrode plate was studied. Unless otherwise noted, the configuration of lead storage batteries, their production method, and their evaluation method were the same as those in the case of the study (A) described above except that the surface roughnesses Ra of the surfaces of positive electrode plates differed from each other. The evaluation results are shown in Table 11.

From the evaluation results shown in Table 11, it is seen that when the surface roughness Ra of the surface of the positive electrode plate is equal to or less than 0.20 mm, the increase in internal resistance is significantly suppressed and the decrease rate of the internal resistance is fast.

TABLE 11

| | | | | | | Internal resistance | | |
|---|---|---|---|---|---|---|---|---|
| | | | | | | increase rate (%) | | |
| | | | Internal resistance (mΩ) | | | | Increase | |
| | | | | | Value | | rate of | |
| | | Surface | | | after | Increase | value | |
| | | roughness | | Value | being | rate of value | after | |
| | Flatness | Ra | Initial | immediately | left | immediately | being | |
| | (mm) | (mm) | value | after charge | still | after charge | left still | Determination |
| Example 501 | 0.5 | 0.00 | 5.3 | 5.4 | 5.3 | 2 | 0 | ○ |
| Example 502 | | 0.10 | 5.3 | 5.5 | 5.3 | 4 | 0 | ○ |
| Example 503 | | 0.20 | 5.3 | 5.5 | 5.4 | 4 | 2 | ○ |
| Example 504 | | 0.30 | 5.3 | 5.8 | 5.7 | 9 | 8 | Δ |
| Example 505 | 1.0 | 0.00 | 5.3 | 5.4 | 5.3 | 2 | 0 | ○ |
| Example 506 | | 0.10 | 5.3 | 5.5 | 5.4 | 4 | 2 | ○ |
| Example 507 | | 0.20 | 5.3 | 5.5 | 5.4 | 4 | 2 | ○ |
| Example 508 | | 0.30 | 5.3 | 6.0 | 5.8 | 13 | 9 | Δ |
| Example 509 | 2.0 | 0.00 | 5.4 | 5.6 | 5.5 | 4 | 2 | ○ |
| Example 510 | | 0.10 | 5.4 | 5.6 | 5.6 | 4 | 4 | ○ |
| Example 511 | | 0.20 | 5.4 | 5.7 | 5.6 | 6 | 4 | ○ |
| Example 512 | | 0.30 | 5.4 | 6.2 | 6.0 | 15 | 11 | Δ |
| Example 513 | 3.0 | 0.00 | 5.4 | 5.6 | 5.5 | 4 | 2 | ○ |
| Example 514 | | 0.10 | 5.4 | 5.7 | 5.6 | 6 | 4 | ○ |
| Example 515 | | 0.20 | 5.4 | 5.8 | 5.6 | 7 | 4 | ○ |
| Example 516 | | 0.30 | 5.4 | 6.2 | 6.0 | 15 | 11 | Δ |
| Example 517 | 4.0 | 0.00 | 5.4 | 5.6 | 5.6 | 4 | 4 | ○ |
| Example 518 | | 0.10 | 5.4 | 5.7 | 5.6 | 6 | 4 | ○ |
| Example 519 | | 0.20 | 5.4 | 5.8 | 5.6 | 7 | 4 | ○ |
| Example 520 | | 0.30 | 5.4 | 6.3 | 6.1 | 17 | 13 | Δ |
| Comparative | 5.0 | 0.00 | 5.5 | 6.1 | 6.0 | 11 | 9 | × |
| Example 501 | | | | | | | | |
| Comparative | | 0.10 | 5.5 | 6.2 | 6.1 | 13 | 11 | × |
| Example 502 | | | | | | | | |
| Comparative | | 0.20 | 5.5 | 6.3 | 6.1 | 15 | 11 | × |
| Example 503 | | | | | | | | |
| Comparative | | 0.30 | 5.5 | 6.4 | 6.3 | 16 | 15 | × |
| Example 504 | | | | | | | | |

(G) Study on Influence of Distance between Positive Electrode Plate and Negative Electrode Plate on Increase in Internal Resistance

The influence of the distance between adjacent positive and negative electrode plates (hereinafter may also be referred to as “the inter-electrode-plate distance”) was studied. Unless otherwise noted, the configuration of lead storage batteries, their production method, and their evaluation method were the same as those in the case of the study (A) described above except that the inter-electrode-plate distances differed from each other. The evaluation results are shown in Table 12.

From the evaluation results shown in Table 12, it is seen that when the inter-electrode-plate distance is equal to or more than 0.60 mm and equal to or less than 0.90 mm, the increase in internal resistance is significantly suppressed and the decrease rate of the internal resistance is fast.

TABLE 12

| | | | | | | Internal resistance | | |
|---|---|---|---|---|---|---|---|---|
| | | | | | | increase rate (%) | | |
| | | | Internal resistance (mΩ) | | | | Increase | |
| | | | | | Value | | rate of | |
| | | Inter- | | | after | Increase | value | |
| | | electrode- | | Value | being | rate of value | after | |
| | Flatness | plate | Initial | immediately | left | immediately | being | |
| | (mm) | distance (mm) | value | after charge | still | after charge | left still | Determination |
| Example 601 | 0.5 | 0.50 | 5.3 | 5.6 | 5.6 | 6 | 6 | Δ |
| Example 602 | | 0.60 | 5.3 | 5.4 | 5.5 | 2 | 4 | ○ |
| Example 603 | | 0.80 | 5.4 | 5.5 | 5.5 | 2 | 2 | ○ |
| Example 604 | | 0.90 | 5.4 | 5.7 | 5.4 | 6 | 0 | ○ |
| Example 605 | | 1.00 | 5.4 | 6.0 | 5.5 | 11 | 2 | Δ |
| Example 606 | 1.0 | 0.50 | 5.3 | 5.6 | 5.6 | 6 | 6 | Δ |
| Example 607 | | 0.60 | 5.3 | 5.6 | 5.5 | 6 | 4 | ○ |
| Example 608 | | 0.80 | 5.4 | 5.6 | 5.6 | 4 | 4 | ○ |
| Example 609 | | 0.90 | 5.5 | 5.8 | 5.6 | 5 | 2 | ○ |
| Example 610 | | 1.00 | 5.5 | 6.1 | 5.6 | 11 | 2 | Δ |
| Example 611 | 2.0 | 0.50 | 5.4 | 5.7 | 5.7 | 6 | 6 | Δ |
| Example 612 | | 0.60 | 5.5 | 5.7 | 5.5 | 4 | 0 | ○ |
| Example 613 | | 0.80 | 5.5 | 5.8 | 5.6 | 5 | 2 | ○ |
| Example 614 | | 0.90 | 5.5 | 5.9 | 5.7 | 7 | 4 | ○ |
| Example 615 | | 1.00 | 5.6 | 6.2 | 5.8 | 11 | 4 | Δ |
| Example 616 | 3.0 | 0.50 | 5.4 | 5.8 | 5.8 | 7 | 7 | Δ |
| Example 617 | | 0.60 | 5.5 | 5.8 | 5.6 | 5 | 2 | ○ |
| Example 618 | | 0.80 | 5.5 | 6.0 | 5.7 | 9 | 4 | ○ |
| Example 619 | | 0.90 | 5.6 | 6.1 | 5.8 | 9 | 4 | ○ |
| Example 620 | | 1.00 | 5.7 | 6.4 | 5.9 | 12 | 4 | Δ |
| Example 621 | 4.0 | 0.50 | 5.4 | 5.9 | 5.8 | 9 | 7 | Δ |
| Example 622 | | 0.60 | 5.4 | 5.9 | 5.6 | 9 | 4 | ○ |
| Example 623 | | 0.80 | 5.5 | 6.0 | 5.7 | 9 | 4 | ○ |
| Example 624 | | 0.90 | 5.6 | 6.1 | 5.7 | 9 | 2 | ○ |
| Example 625 | | 1.00 | 5.7 | 6.4 | 5.9 | 12 | 4 | Δ |
| Comparative | | 0.50 | 5.5 | 6.4 | 6.4 | 16 | 16 | × |
| Example 601 | | | | | | | | |
| Comparative | 5.0 | 0.60 | 5.5 | 6.4 | 6.4 | 16 | 16 | × |
| Example 602 | | | | | | | | |
| Comparative | | 0.80 | 5.5 | 6.6 | 6.5 | 20 | 18 | × |
| Example 603 | | | | | | | | |
| Comparative | | 0.90 | 5.5 | 6.7 | 6.6 | 22 | 20 | × |
| Example 604 | | | | | | | | |
| Comparative | | 1.00 | 5.6 | 6.8 | 6.7 | 21 | 20 | × |
| Example 605 | | | | | | | | |

H) Study on Influence of Concentration of Aluminum Ions in Electrolyte on Increase in Internal Resistance and Charge Acceptance Performance

The influence of the concentration of aluminum ions in an electrolyte was studied. Unless otherwise noted, the configuration of lead storage batteries and their production method were the same as those in the case of the study (A) described above except that the concentrations of aluminum ions in electrolytes differed from each other. For the performance of the lead acid battery, the increase in internal resistance was evaluated like in the study (A) described above, and the charge acceptance performance was also evaluated.

The charge acceptance performance was evaluated as follows. The lead acid battery was fully charged, and after confirming that the temperature of the electrolyte was in a range equal to or more than 23° C. and equal to or less than 27° C., the lead acid battery was discharged at a 5-hour rate current for 0.5 hours. Then, the lead acid battery was left still for 20 hours at a temperature equal to or more than 23° C. and equal to or less than 27° C., and after confirming that the temperature of the electrolyte was in a range equal to or more than 23° C. and equal to or less than 27° C., the constant voltage charge was performed under conditions of a temperature equal to or more than 23° C. and equal to or less than 27° C., a voltage equal to or more than 13.9 V and equal to or less than 14.1 V, and a maximum current of 100 A, and the charge current after 5 seconds from the start of the charge was measured.

The evaluation results are shown in Table 13. For the evaluation results of the charge acceptance performance, when the charge current is higher by 10 A or more compared to a reference example in which the concentration of aluminum ions in the electrolyte is 0 mol/L, a mark ∘ is given in Table 13, and when the charge current is higher by a value more than 0 A and less than 10 A, a mark Δ is given in Table 13. When the charge current is equal to or less than that of the reference example, a mark × is given in Table 13.

Further, the evaluation results of the increase rate of the internal resistance and the charge acceptance performance were synthesized to make a total determination. The results are shown in Table 13. In Table 13, when the increase rate of the internal resistance and the charge acceptance performance are both given a mark ∘, a mark ∘ is given as a total determination, and when at least one of the increase rate of the internal resistance and the charge acceptance performance is given a mark Δ or a mark × a mark × is given as a total determination.

TABLE 13

| | | | | | | Internal resistance | | | | | |
|---|---|---|---|---|---|---|---|---|---|---|---|
| | | | | | | increase rate (%) | | | | | |
| | | Con- | | | | | Increase | | Charge | | |
| | | centration | Internal resistance (mΩ) | | | | rate of | | acceptance | | |
| | | of | | | Value | Increase | value | | performance | | |
| | | aluminum | | Value | after | rate of value | after | | Charge | | Total |
| | Flatness | ion | Initial | immediately | being | immediately | being | Deter- | current | Deter- | deter- |
| | (mm) | (mol/L) | value | after charge | left still | after charge | left still | mination | (A) | mination | mination |
| Reference | 1.0 | 0 | 5.1 | 5.3 | 5.2 | 4 | 2 | ○ | 40 | — | — |
| Example | | | | | | | | | | | |
| Example 701 | 0.5 | 0.005 | 5.2 | 5.4 | 5.3 | 4 | 2 | ○ | 40 | × | × |
| Example 702 | | 0.010 | 5.2 | 5.5 | 5.3 | 6 | 2 | ○ | 51 | ○ | ○ |
| Example 703 | | 0.100 | 5.3 | 5.6 | 5.4 | 6 | 2 | ○ | 54 | ○ | ○ |
| Example 704 | | 0.300 | 5.3 | 5.7 | 5.5 | 8 | 4 | ○ | 57 | ○ | ○ |
| Example 705 | | 0.400 | 5.5 | 6.1 | 6.0 | 11 | 9 | × | 55 | ○ | × |
| Example 706 | 1.0 | 0.005 | 5.2 | 5.4 | 5.3 | 4 | 2 | ○ | 40 | × | × |
| Example 707 | | 0.010 | 5.3 | 5.5 | 5.4 | 4 | 2 | ○ | 51 | ○ | ○ |
| Example 708 | | 0.100 | 5.4 | 5.6 | 5.5 | 4 | 2 | ○ | 55 | ○ | ○ |
| Example 709 | | 0.300 | 5.4 | 5.7 | 5.6 | 6 | 4 | ○ | 57 | ○ | ○ |
| Example 710 | | 0.400 | 5.7 | 6.3 | 6.2 | 11 | 9 | × | 54 | ○ | × |
| Example 711 | 2.0 | 0.005 | 5.3 | 5.4 | 5.4 | 2 | 2 | ○ | 39 | × | × |
| Example 712 | | 0.010 | 5.3 | 5.7 | 5.5 | 8 | 4 | ○ | 51 | ○ | ○ |
| Example 713 | | 0.100 | 5.4 | 5.8 | 5.6 | 7 | 4 | ○ | 53 | ○ | ○ |
| Example 714 | | 0.300 | 5.5 | 5.9 | 5.8 | 7 | 5 | ○ | 55 | ○ | ○ |
| Example 715 | | 0.400 | 5.8 | 6.5 | 6.4 | 12 | 10 | × | 52 | ○ | × |
| Example 716 | 3.0 | 0.005 | 5.4 | 5.7 | 5.5 | 6 | 2 | ○ | 38 | × | × |
| Example 717 | | 0.010 | 5.4 | 5.8 | 5.6 | 7 | 4 | ○ | 50 | ○ | ○ |
| Example 718 | | 0.100 | 5.5 | 5.9 | 5.7 | 7 | 4 | ○ | 52 | ○ | ○ |
| Example 719 | | 0.300 | 5.6 | 5.9 | 5.7 | 5 | 2 | ○ | 54 | ○ | ○ |
| Example 720 | | 0.400 | 5.9 | 6.6 | 6.4 | 12 | 8 | × | 51 | ○ | × |
| Example 721 | 4.0 | 0.005 | 5.4 | 5.8 | 5.7 | 7 | 6 | Δ | 38 | × | × |
| Example 722 | | 0.010 | 5.5 | 5.9 | 5.7 | 7 | 4 | ○ | 50 | ○ | ○ |
| Example 723 | | 0.100 | 5.5 | 6.0 | 5.8 | 9 | 5 | ○ | 52 | ○ | ○ |
| Example 724 | | 0.300 | 5.6 | 6.0 | 5.9 | 7 | 5 | ○ | 53 | ○ | ○ |
| Example 725 | | 0.400 | 5.9 | 6.8 | 6.6 | 15 | 12 | × | 49 | Δ | × |
| Comparative | 5.0 | 0.005 | 5.5 | 6.4 | 6.3 | 16 | 15 | × | 36 | × | × |
| Example 701 | | | | | | | | | | | |
| Comparative | | 0.010 | 5.6 | 6.4 | 6.4 | 14 | 14 | × | 49 | Δ | × |
| Example 702 | | | | | | | | | | | |
| Comparative | | 0.100 | 5.7 | 6.5 | 6.5 | 14 | 14 | × | 48 | Δ | × |
| Example 703 | | | | | | | | | | | |
| Comparative | | 0.300 | 5.8 | 6.6 | 6.6 | 14 | 14 | × | 46 | Δ | × |
| Example 704 | | | | | | | | | | | |
| Comparative | | 0.400 | 6.0 | 6.9 | 6.8 | 15 | 13 | × | 43 | Δ | × |
| Example 705 | | | | | | | | | | | |

It is known that when aluminum ions are added to an electrolyte, the charge acceptance performance is improved. However, it has been found that when aluminum ions are added to an electrolyte in a lead acid battery using electrode plates with a large flatness, gas stays between the electrode plates due to an increase in flatness to increase the internal resistance so that the effect of addition of aluminum ions is decreased.

Further, it has been found that when aluminum ions or sodium ions are excessively added to an electrolyte, since the resistance and viscosity of the electrolyte increase, gas is hard to release so that the internal resistance is more likely to increase. Therefore, it is important to make proper the concentrations of aluminum ions and sodium ions in the electrolyte, as well as the flatness.

(I) Study on Influence of Concentration of Sodium Ions in Electrolyte on Increase in Internal Resistance and Charge Acceptance Performance

The influence of the concentration of sodium ions in an electrolyte was studied. Unless otherwise noted, the configuration of lead storage batteries and their production method were the same as those in the case of the study (H) described above except that the concentrations of aluminum ions and sodium ions in electrolytes differed from each other. For the performance of the lead acid battery, the increase in internal resistance and the charge acceptance performance were evaluated like in the study (H) described above, and the battery life was also evaluated like in the study (C) described above.

The evaluation results are shown in Table 14. For the evaluation results of the battery life, when the battery life is equal to or more than 800 cycles, a mark ∘ is given in Table 14, and when the battery life is less than 800 cycles, a mark × is given in Table 14.

Further, the evaluation results of the increase rate of the internal resistance, the charge acceptance performance, and the battery life were synthesized to make a total determination. The results are shown in Table 14. In Table 14, when the increase rate of the internal resistance, the charge acceptance performance, and the battery life are all given a mark ∘, a mark ∘ is given as a total determination, and when at least one of the increase rate of the internal resistance, the charge acceptance performance, and the battery life is given a mark Δ or a mark ×, a mark × is given as a total determination.

TABLE 14

| | | | | | | | Internal resistance | | | | | | | |
|---|---|---|---|---|---|---|---|---|---|---|---|---|---|---|
| | | | | | | | increase rate (%) | | | | | | | |
| | | Con- | Con- | | | | | Increase | | Charge | | Battery | | |
| | | centration | centration | Internal resistance (mΩ) | | | | rate of | | acceptance | | life | | |
| | | of | of | | | Value | Increase | value | | performance | | Num- | | Total |
| | Flat- | aluminum | sodium | | Value | after | rate of value | after | Deter- | Charge | Deter- | ber | Deter- | deter- |
| | ness | ion | ion | Initial | immediately | being | immediately | being | mina- | current | mina- | of | mina- | mina- |
| | (mm) | (mol/L) | (mol/L) | value | after charge | left still | after charge | left still | tion | (A) | tion | cycles | tion | tion |
| Example 801 | 2.0 | 0.100 | 0.001 | 5.4 | 5.8 | 5.6 | 7 | 4 | ○ | 52 | ○ | 700 | × | × |
| Example 802 | | | 0.002 | 5.4 | 5.8 | 5.6 | 7 | 4 | ○ | 53 | ○ | 920 | ○ | ○ |
| Example 803 | | | 0.010 | 5.7 | 6.1 | 5.8 | 7 | 2 | ○ | 51 | ○ | 980 | ○ | ○ |
| Example 804 | | | 0.050 | 5.8 | 6.2 | 6.0 | 7 | 3 | ○ | 51 | ○ | 950 | ○ | ○ |
| Example 805 | | | 0.060 | 6.0 | 6.6 | 6.5 | 10 | 8 | × | 43 | Δ | 980 | ○ | × |

It has been found that the presence of sodium ions in the electrolyte is harmful and impedes the charge rate improvement effect by aluminum ions and so on. The concentration of sodium ions in the electrolyte is preferably equal to or more than 0.002 mol/L and equal to or less than 0.05 mol/L.

Since a lignin used as a negative electrode additive is generally a sodium salt, when the concentration of sodium ions is less than 0.002 mol/L, this leads to a decrease in the addition amount of the lignin and, in this regard, decreases the life of the lead acid battery instead.

(J) Study on Influence of Content of Iron Contained in Positive Active Material on Increase in Internal Resistance

First, plate-like grids made of a Pb-Ca-based or Pb-Ca-Sn-based lead alloy were cast, and a current collection lug was formed at a predetermined position of each of the plate-like grids. The plate-like grid may be produced by a continuous production method, not limited to a casting method. As the continuous production method, there can be cited a punching method that produces the plate-like grid by punching a sheet (e.g. a rolled sheet) of lead or lead alloy (punching method), or an expanding method that punches a lead or lead alloy sheet and then expands the sheet in the direction parallel to the sheet surface, thereby forming a grid structure.

Then, a lead powder mainly composed of lead monoxide was kneaded with water and dilute sulfuric acid, and as needed, was further kneaded by mixing an additive, thereby producing a paste of a positive active material. Likewise, a lead powder mainly composed of lead monoxide was kneaded with water and dilute sulfuric acid, and as needed, was further kneaded by mixing an additive, thereby producing a paste of a negative active material.

Then, after filling the paste of the positive active material in the plate-like grids, maturation and drying were performed. Likewise, after filling the paste of the negative active material in the plate-like grids, maturation and drying were performed. Positive electrode plates and negative electrode plates produced as described above were alternately stacked with separators, made of a porous synthetic resin, interposed therebetween, thereby producing an electrode plate group. The electrode plate group was housed in a battery case. The current collection lugs of the positive electrode plates were joined together by a positive electrode strap, and the current collection lugs of the negative electrode plates were joined together by a negative electrode strap. Then, the positive electrode strap was connected to one end of a positive electrode terminal, and the negative electrode strap was connected to one end of a negative electrode terminal. The battery size was M-42 in which the number of the positive electrode plates and the number of the negative electrode plates forming the electrode plate group were respectively set to six and seven.

Further, an opening of the battery case was closed with a lid. The positive electrode terminal and the negative electrode terminal were made to pass through the lid so that the other end of the positive electrode terminal and the other end of the negative electrode terminal were exposed to the outside of a lead acid battery. An electrolyte was injected through a liquid injection port formed in the lid, then the liquid injection port was sealed with a plug, and then battery case chemical conversion was performed. The time from the injection of the electrolyte until the start of energization for the chemical conversion (i.e. the soaking time) was set to 30 minutes, and the amount of electricity for the chemical conversion was set to 230%.

Sulfuric acid containing a predetermined amount of iron was used as the electrolyte. This electrolyte was prepared by adding ferrous sulfate to industrial sulfuric acid. See Table 15 for the contents of iron in the electrolytes. The specific gravities of the prepared electrolytes were each 1.23. Since iron moves to the positive electrodes during the charge and to the negative electrodes during the discharge via the electrolyte, iron contained in the electrolyte before chemical conversion is moved to the positive electrodes after chemical conversion (in the fully charged state). Therefore, the content of iron in the electrolyte before chemical conversion and the content of iron contained in the positive active material in the fully charged state take approximately the same value.

By the chemical conversion described above, there was obtained a lead acid battery including the chemically converted positive electrode plates each formed with active material layers of the positive active material containing lead dioxide on both plate surfaces of the electrode plate and the chemically converted negative electrode plates each formed with active material layers of the negative active material containing metallic lead on both plate surfaces of the electrode plate.

The flatness of the positive electrode plate after chemical conversion was adjusted by changing the thick coating degree ratio between the active material layers of the positive active material formed on both plate surfaces of the positive electrode plate before chemical conversion. However, a method to adjust the flatness of the positive electrode plate after chemical conversion is not limited to the method that changes the thick coating degree ratio, and another method may alternatively be used. A method to measure the flatness of the positive electrode plate after chemical conversion will be described in detail later.

The thickness of the separator was adjusted so that a predetermined group pressure was applied to the electrode plate group. The density of the positive active material included in the positive electrode plate was 4.4 g/cm³. The ratio α/(α+β) between the mass a of α-lead dioxide and the mass β of β-lead dioxide contained in the positive active material was 30%. The average diameter of pores included in the positive active material was 0.10 μm, and the porosity of the positive active material was 30%. The surface roughness Ra of the surface of the positive electrode plate was 0.10 mm. The distance between the adjacent positive and negative electrode plates was 0.60 mm. As the electrolyte, use was made of one containing aluminum sulfate in a concentration of 0.1 mol/L.

Then, the flatness of the positive electrode plate and the content of iron contained in the positive active material were measured immediately after the end of the chemical conversion. The results are shown in Table 15. The flatness of the positive electrode plate was measured as follows. First, the thickness is measured at a plurality of portions of the positive electrode plate using a micrometer, and the average value of the measured values is set as the thickness of the positive electrode plate. Then, as illustrated in FIG. 2, the positive electrode plate is placed on the flat surface of the base such that the plate surfaces of the positive electrode plate and the flat surface of the base are generally parallel to each other with the convex surface of the curved positive electrode plate facing upward, and the distance h between the apex of the convex surface of the curved positive electrode plate and the flat surface of the base is measured using a height gauge. Then, a value obtained by subtracting the thickness of the positive electrode plate from the distance h is set as the flatness.

Then, after the initial charge was performed for the produced lead acid battery, aging was performed for 48 hours. Then, the internal resistance of the lead acid battery was measured. This internal resistance measured value was set as an “initial value”.

Subsequently, the constant voltage charge was performed for the lead acid battery in the fully charged state after the aging, and the internal resistance immediately after the end of the constant voltage charge was measured. This internal resistance measured value was set as a “value immediately after charge”. The conditions of the constant voltage charge were a maximum current of 100 A, a control voltage of 14.0 V, and a charge time of 10 minutes (this lead acid battery had a 5-hour rate capacity (rated capacity) of 32 Ah).

The lead acid battery was left still for an hour after the end of the constant voltage charge, and the internal resistance after being left still was measured. This internal resistance measured value was set as a “value after being left still”.

These results are shown in Table 15. The increase rate of the internal resistance was calculated using the initial value, the value immediately after charge, and the value after being left still, of the internal resistance. The increase rate of the value immediately after charge to the initial value was calculated by ([value immediately after charge]−[initial value])/[initial value], and the increase rate of the value after being left still to the initial value was calculated by ([value after being left still]−[initial value])/[initial value].

When a condition A that the increase rate of the value immediately after charge to the initial value is equal to or less than 10%, and a condition B that the increase rate of the value after being left still to the initial value is equal to or less than 5% or that the increase rate of the value after being left still is a value that is lower by 4% or more than the increase rate of the value immediately after charge are both satisfied, it is determined that the increase in internal resistance is significantly suppressed, and a mark ∘ is given in Table 15.

When only either one of the condition A and the condition B is satisfied, it is determined that while the increase in internal resistance is sufficiently suppressed, it cannot be said to be significantly suppressed, and a mark Δ is given in Table 15. When neither of the condition A and the condition B is satisfied, it is determined that the suppression of the increase in internal resistance is slightly insufficient or totally insufficient, and a mark × is given in Table 15.

The stratification of the electrolyte and the battery life were evaluated by a 17.5% DOD life test defined in EN 50342-6:2015 of the European standard (EN standard). Specifically, the following operations (1), (2), and (3) were repeated in cycles, and it was determined that the life had been reached when the voltage became 10 V, and then, the number of the cycles performed until then was set as the battery life, and the difference in specific gravity between upper and lower portions of the electrolyte and the liquid reduction amount of the electrolyte were measured at an ambient temperature of 25° C.

(1) The state of charge (SOC) is adjusted to 50%.

(2) The charge and discharge at a discharge depth (DOD) of 17.5% are repeated 85 times.

(3) The battery is fully charged, and a 20 HR capacity test is performed. After the end of the capacity test, the full charge is performed again.

The evaluation results are shown in Table 15. For the stratification of the electrolyte, when the difference in specific gravity between upper and lower portions of the electrolyte is less than 0.100, a mark ∘ is given in Table 15, when it is equal to or more than 0.100 and equal to or less than 0.145, a mark Δ is given in Table 15, and when it is more than 0.145, a mark × is given in Table 15.

When the liquid reduction amount of the electrolyte is less than 36.0 g, a mark ∘ is given in Table 15, when it is equal to or more than 36.0 g and equal to or less than 40.0 g, a mark Δ is given in Table 15, and when it is more than 40.0 g, a mark × is given in Table 15. The original electrolyte amount before the liquid reduction is 475 g.

Further, both determination results of the difference in specific gravity between upper and lower portions of the electrolyte and the liquid reduction amount of the electrolyte were combined to perform an integrated evaluation. In Table 15, when both determination results are ∘, a mark ∘ is given, when one of the determination results is Δ and the other one of the determination results is ∘ or Δ, a mark Δ is given, and when at least one of the determination results is ×, a mark × is given.

Further, the integrated evaluation combining the difference in specific gravity of the electrolyte and the liquid reduction amount of the electrolyte and the determination result of the increase rate of the internal resistance were synthesized to make a total determination. In Table 15, when one of the determination results is ◯ and the other one of the determination results is ∘ or Δ, a mark ∘ is given, when both determination results are Δ, a mark Δ is given, and when at least one of the determination results is ×, a mark × is given.

TABLE 15

| | | | | Specific gravity | | | | Integrated | | | | Internal resistance | | | |
|---|---|---|---|---|---|---|---|---|---|---|---|---|---|---|---|
| | | | | of electrolyte | | Liquid | | evaluation | | | | increase rate (%) | | | |
| | | | | Difference | | reduction | | of specific | Internal | | | Increase | Increase | | |
| | | | Iron | in specific | | of electrolyte | | gravity | resistance (mΩ) | | | rate of | rate of | | |
| | | Iron | content | gravity | | Liquid | | difference | | Value | Value | value | value | | |
| | | content | in | between | | re- | | and | | imme- | after | imme- | after | | Total |
| | Flat- | in | active | upper | Deter- | duction | Deter- | liquid | | diately | being | diately | being | Deter- | deter- |
| | ness | electrolyte | material | and lower | mina- | amount | mina- | reduction | Initial | after | left | after | left | mina- | mina- |
| | (mm) | (ppm) | (ppm) | portions | tion | (g) | tion | amount | value | charge | still | charge | still | tion | tion |
| Example 901 | 2.0 | 0 | 3.5 | 0.101 | Δ | 35.6 | ○ | Δ | 5.2 | 5.4 | 5.3 | 4 | 2 | ○ | ○ |
| Example 902 | | 5 | 4.0 | 0.087 | ○ | 36.7 | Δ | Δ | 5.3 | 5.5 | 5.4 | 4 | 2 | ○ | ○ |
| Example 903 | | 10 | 10.0 | 0.067 | ○ | 38.2 | Δ | Δ | 5.4 | 5.6 | 5.5 | 4 | 2 | ○ | ○ |
| Example 904 | | 25 | 20.0 | 0.031 | ○ | 39.1 | Δ | Δ | 5.4 | 5.7 | 5.5 | 6 | 2 | ○ | ○ |
| Comparative | | 50 | 35.0 | 0.014 | ○ | 45.2 | × | × | 5.5 | 6.1 | 6.0 | 11 | 9 | × | × |
| Example 901 | | | | | | | | | | | | | | | |
| Example 905 | 1.0 | 0 | 3.5 | 0.106 | Δ | 35.4 | ○ | Δ | 5.2 | 5.4 | 5.3 | 4 | 2 | ○ | ○ |
| Example 906 | | 5 | 4.0 | 0.097 | ○ | 36.6 | Δ | Δ | 5.3 | 5.6 | 5.4 | 6 | 2 | ○ | ○ |
| Example 907 | | 10 | 10.0 | 0.073 | ○ | 37.9 | Δ | Δ | 5.4 | 5.7 | 5.5 | 6 | 2 | ○ | ○ |
| Example 908 | | 25 | 20.0 | 0.035 | ○ | 38.9 | Δ | Δ | 5.5 | 5.8 | 5.6 | 5 | 2 | ○ | ○ |
| Comparative | | 50 | 35.0 | 0.016 | ○ | 45.2 | × | × | 5.6 | 6.3 | 6.2 | 13 | 11 | × | × |
| Example 902 | | | | | | | | | | | | | | | |
| Example 909 | 2.0 | 0 | 3.5 | 0.114 | Δ | 35.7 | ○ | Δ | 5.3 | 5.5 | 5.5 | 4 | 4 | ○ | ○ |
| Example 910 | | 5 | 4.0 | 0.109 | Δ | 36.7 | Δ | Δ | 5.3 | 5.7 | 5.5 | 8 | 4 | ○ | ○ |
| Example 911 | | 10 | 10.0 | 0.082 | ○ | 37.8 | Δ | Δ | 5.4 | 5.8 | 5.6 | 7 | 4 | ○ | ○ |
| Example 912 | | 25 | 20.0 | 0.039 | ○ | 39.2 | Δ | Δ | 5.5 | 6.0 | 5.8 | 9 | 5 | ○ | ○ |
| Comparative | | 50 | 35.0 | 0.018 | ○ | 45.2 | × | × | 5.8 | 6.5 | 6.4 | 12 | 10 | × | × |
| Example 903 | | | | | | | | | | | | | | | |
| Example 913 | 3.0 | 0 | 3.5 | 0.126 | Δ | 35.7 | ○ | Δ | 5.4 | 5.7 | 5.5 | 6 | 2 | ○ | ○ |
| Example 914 | | 5 | 4.0 | 0.121 | Δ | 36.4 | Δ | Δ | 5.4 | 5.8 | 5.6 | 7 | 4 | ○ | ○ |
| Example 915 | | 10 | 10.0 | 0.091 | ○ | 37.8 | Δ | Δ | 5.5 | 6.0 | 5.7 | 9 | 4 | ○ | ○ |
| Example 916 | | 25 | 20.0 | 0.044 | ○ | 38.9 | Δ | Δ | 5.6 | 6.1 | 5.8 | 9 | 4 | ○ | ○ |
| Comparative | | 50 | 35.0 | 0.020 | ○ | 45.2 | × | × | 5.9 | 6.6 | 6.4 | 12 | 8 | Δ | × |
| Example 904 | | | | | | | | | | | | | | | |
| Example 917 | 4.0 | 0 | 3.5 | 0.138 | Δ | 35.7 | ○ | Δ | 5.5 | 5.9 | 5.6 | 7 | 2 | ○ | ○ |
| Example 918 | | 5 | 4.0 | 0.130 | Δ | 36.7 | Δ | Δ | 5.6 | 5.9 | 5.7 | 5 | 2 | ○ | ○ |
| Example 919 | | 10 | 10.0 | 0.103 | Δ | 37.9 | Δ | Δ | 5.7 | 6.0 | 5.8 | 5 | 2 | ○ | ○ |
| Example 920 | | 25 | 20.0 | 0.067 | ○ | 39.2 | Δ | Δ | 5.7 | 6.2 | 6.0 | 9 | 5 | ○ | ○ |
| Comparative | | 50 | 35.0 | 0.032 | ○ | 45.2 | × | × | 5.9 | 6.8 | 6.6 | 15 | 12 | × | × |
| Example 905 | | | | | | | | | | | | | | | |
| Comparative | 5.0 | 0 | 3.5 | 0.150 | × | 35.7 | ○ | × | 5.6 | 6.5 | 6.3 | 16 | 13 | × | × |
| Example 906 | | | | | | | | | | | | | | | |
| Comparative | | 5 | 4.0 | 0.145 | Δ | 36.3 | Δ | Δ | 5.7 | 6.4 | 6.4 | 12 | 12 | × | × |
| Example 907 | | | | | | | | | | | | | | | |
| Comparative | | 10 | 10.0 | 0.115 | Δ | 38.1 | Δ | Δ | 5.8 | 6.6 | 6.5 | 14 | 12 | × | × |
| Example 908 | | | | | | | | | | | | | | | |
| Comparative | | 25 | 20.0 | 0.079 | ○ | 39.2 | Δ | Δ | 5.9 | 6.7 | 6.6 | 14 | 12 | × | × |
| Example 909 | | | | | | | | | | | | | | | |
| Comparative | | 50 | 35.0 | 0.055 | ○ | 44.8 | × | × | 6.1 | 7.0 | 6.9 | 15 | 13 | × | × |
| Example 910 | | | | | | | | | | | | | | | |

First, from the relationship between the flatness and the internal resistance in Table 15, it is seen that the smaller the flatness, the lower the internal resistance. This is considered to be because as the flatness decreases, gas is hard to stay on the surface of the positive electrode plate and tends to be discharged to the outside of the electrode plate group so that an increase in the internal resistance of the lead acid battery is suppressed. When the flatness of the positive electrode plate after chemical conversion is equal to or less than 4.0 mm, an increase in the internal resistance of the lead acid battery is sufficiently suppressed so that it is possible to accurately determine the state of charge or the state of degradation by a method of measuring the internal resistance.

There was a tendency that the lower the content of iron contained in the positive active material in the fully charged state, the greater the difference in specific gravity between upper and lower portions of the electrolyte, and the stratification tended to occur. There was a tendency that the higher the content of iron contained in the positive active material in the fully charged state, the smaller the difference in specific gravity between upper and lower portions of the electrolyte, and the stratification was suppressed. For example, in Comparative Example 906, the difference in specific gravity was large meaning that the stratification was occurring, while, in Comparative Examples 907 and 908, the difference in specific gravity was smaller than Comparative Example 906, and in Comparative Examples 909 and 910, the difference in specific gravity was even smaller, meaning that the stratification was suppressed. In the lead storage batteries with the same flatness (e.g. in Examples 905 to 908 and Comparative Example 2 502 in which the flatness was 1.0 mm), the same tendency as described above was observed.

On the other hand, the liquid reduction amount of the electrolyte had a tendency opposite to the difference in specific gravity between upper and lower portions of the electrolyte. There was a tendency that the lower the content of iron contained in the positive active material in the fully charged state, the smaller the liquid reduction amount of the electrolyte, and there was a tendency that the higher the content of iron contained in the positive active material in the fully charged state, the greater the liquid reduction amount of the electrolyte.

On the other hand, in the lead storage batteries in which the content of iron contained in the positive active material in the fully charged state was the same (e.g. in Examples 902, 906, 910, 914, and 918 and Comparative Example 907 in which the content of iron was 4.00 ppm), there was observed a tendency that the smaller the flatness, the smaller the difference in specific gravity between upper and lower portions of the electrolyte. As the flatness decreases, the interval between the positive electrode plate and the negative electrode plate and the interval between the positive electrode plate and the separator decrease, and therefore, gas is hard to stay in a gap between the positive electrode plate and the negative electrode plate or a gap between the positive electrode plate and the separator so that more gas is discharged into the electrolyte. As a result, it is considered that since the stirring of the electrolyte is performed more efficiently, the stratification is suppressed.

Further, as the content of iron contained in the positive active material in the fully charged state increases, the amount of gas produced from the positive electrode and the negative electrode during the charge increases, and therefore, the stirring of the electrolyte is performed more efficiently so that the stratification is suppressed. Further, as the flatness of the positive electrode plate decreases, gas produced from the positive electrode and the negative electrode is hard to stay in a gap between the positive electrode plate and the negative electrode plate so that more gas is discharged into the electrolyte. As a result, it is considered that since the stirring of the electrolyte is performed more efficiently, the stratification is suppressed.

(K) Study on Influence of Ratio between Thicknesses of Positive Active Material Layers on Increase in Internal Resistance

First, plate-like grids made of a Pb-Ca-based or Pb-Ca-Sn-based lead alloy were produced by a casting method or a continuous production method, and a current collection lug was formed at a predetermined position of each of the plate-like grids. As the continuous production method, a punching method that punches a rolled sheet of a lead alloy using a pressing machine or the like (punching method) was employed.

A substrate (plate-like grid) produced by the continuous production method is small in thickness variation compared to a substrate (plate-like grid) produced by the casting method. Specifically, since the thickness of the substrate produced by the continuous production method depends on the thickness of a sheet prepared in advance, the influence of the skill level of a producer or the accuracy of a mold to be used is small compared to the casting method so that the variation is unlikely to occur. Therefore, when a positive electrode plate is produced using the substrate produced by the continuous production method, the variation in the thickness of the positive electrode plate is smaller than when the substrate produced by the casting method is used, and therefore, the curvature of the positive electrode plate in chemical conversion is suppressed. The variation in the thickness of the positive electrode plate is preferably small, and a parameter R (details will be described later) representing the degree of variation in the thickness of the positive electrode plate is preferably in a range equal to or more than 10 μm and equal to or less than 30 μm.

Then, a lead powder mainly composed of lead monoxide was kneaded with water and dilute sulfuric acid, and as needed, was further kneaded by mixing an additive, thereby producing a paste of a positive active material. Likewise, a lead powder mainly composed of lead monoxide was kneaded with water and dilute sulfuric acid, and as needed, was further kneaded by mixing an additive, thereby producing a paste of a negative active material.

Then, after filling the paste of the positive active material in the plate-like grids, maturation and drying were performed. Likewise, after filling the paste of the negative active material in the plate-like grids, maturation and drying were performed. Positive electrode plates and negative electrode plates produced as described above were alternately stacked with separators, made of a porous synthetic resin, interposed therebetween, thereby producing an electrode plate group. The electrode plate group was housed in a battery case. The current collection lugs of the positive electrode plates were joined together by a positive electrode strap, and the current collection lugs of the negative electrode plates were joined together by a negative electrode strap. The positive electrode strap was connected to one end of a positive electrode terminal, and the negative electrode strap was connected to one end of a negative electrode terminal. The battery size was D31. The group pressure was adjusted by the thickness of the separator.

Further, an opening of the battery case was closed with a lid. The positive electrode terminal and the negative electrode terminal were made to pass through the lid so that the other end of the positive electrode terminal and the other end of the negative electrode terminal were exposed to the outside of a lead acid battery. An electrolyte was injected through a liquid injection port formed in the lid, then the liquid injection port was sealed with a plug, and then battery case chemical conversion was performed. Sulfuric acid containing a predetermined amount of aluminum ions was used as the electrolyte. This electrolyte was prepared by adding aluminum sulfate to industrial sulfuric acid.

By the chemical conversion, there was obtained a lead acid battery including the chemically converted positive electrode plates each formed with active material layers of the positive active material containing lead dioxide on both plate surfaces of the electrode plate and the chemically converted negative electrode plates each formed with active material layers of the negative active material containing metallic lead on both plate surfaces of the electrode plate.

Various measurements and evaluations were performed for the obtained lead storage batteries of Examples 1001 to 1060, Comparative Examples 1001 to 1039, and a conventional example. The contents and methods of the measurements and the evaluations will be described below.

The densities of the positive active materials included in the positive electrode plates were as shown in Tables 16 to 19. The ratio α/(α+β) between the mass a of α-lead dioxide and the mass β of β-lead dioxide contained in the positive active material was 30%. The average diameter of pores included in the positive active material was 0.10 μm, and the porosity of the positive active material was 30%. The surface roughness Ra of the surface of the positive electrode plate was 0.10 mm. The distance between the adjacent positive and negative electrode plates was 0.60 mm. As the electrolyte, use was made of one containing aluminum sulfate in a concentration of 0.1 mol/L.

Flatness of Positive Electrode Plate

The flatness of the positive electrode plate after chemical conversion was measured. The flatness of the positive electrode plate was adjusted by changing the thick coating degree ratio between the active material layers of the positive active material formed on both plate surfaces of the positive electrode plate before chemical conversion. The thick coating degree ratios and the flatnesses were as shown in Tables 16 to 19. The flatness of the positive electrode plate after chemical conversion was measured as follows.

First, the thickness is measured at a plurality of portions of the positive electrode plate using a micrometer, and the average value of the measured values is set as the thickness of the positive electrode plate. Then, as illustrated in FIG. 2, the positive electrode plate is placed on the flat surface of the base such that the plate surfaces of the positive electrode plate and the flat surface of the base are generally parallel to each other with the convex surface of the curved positive electrode plate facing upward, and the distance h between the apex of the convex surface of the curved positive electrode plate and the flat surface of the base is measured using a height gauge. Then, a value obtained by subtracting the thickness of the positive electrode plate from the distance h is set as the flatness.

Degree of Variation in Thickness of Positive Electrode Plate

The degree of variation in the thickness of the positive electrode plate after chemical conversion was evaluated as follows. Using a micrometer manufactured by Mitutoyo Corporation, the thickness of the positive electrode plate was measured. Measurement portions were portions in the vicinity of the corners of the rectangular positive electrode plate and a central portion thereof, i.e., five portions in total. Measured values were substituted into the following formula to calculate a parameter R (unit is μm) representing the degree of variation in the thickness of the positive electrode plate.

$$R = \sqrt{\frac{{\sum }_{i = 1}^{n} \vert {T}_{i} - {T}_{ave} \vert}{n}} \qquad Formula 1$$

In the above formula, Ti represents each of the measured values of the thickness of the positive electrode plate, Tave represents an average value calculated from the measured values of the thickness of the positive electrode plate, and n represents the number of measurements of the thickness of the positive electrode plate (five in the case of this example).

The evaluation results of the variation in thickness are shown in Tables 16 to 19. The substrates produced by the casting method were used for the positive electrode plates with parameters R of 30 μm and 50 μm. The substrates produced by the continuous production method were used for the positive electrode plates with parameters R of 10 μm and 15 μm.

Charge Acceptance Performance

At an ambient temperature of 25° C., the constant current discharge was performed at a 5-hour rate current for 30 minutes, and after adjusting the state of charge (SOC) to 90%, the constant current-constant voltage charge was performed at a current of 100 A and a voltage of 14.0 V for 60 seconds. In this event, the charge current after 5 seconds from the start of the constant current-constant voltage charge was measured, and the charge acceptance performance was evaluated by this charge current.

The results are shown in Tables 16 to 19. The numerical values of the charge current shown in Tables 16 to 19 are the relative values given that the charge current of the lead acid battery of the conventional example is 100. When the charge current was greater than 100, it was determined that the charge acceptance performance was excellent.

Evaluation of Stratification of Electrolyte and Battery Life

The stratification of the electrolyte and the battery life were evaluated by a 17.5% DOD life test defined in EN 50342-6:2015 of the European standard (EN standard). Specifically, the stratification of the electrolyte and the battery life were evaluated by repeatedly performing the following operations (1), (2), and (3).

(1) For the lead acid battery in the fully charged state, the constant current discharge is performed at a current of 4×I20 (I20 is a 20-hour rate current and the unit is A) for 2.5 hours at an ambient temperature of 25° C., thereby adjusting the state of charge (SOC) to 50%.

(2) After the adjustment of the state of charge described above has ended, an operation is repeated in 85 cycles, wherein the operation as one cycle includes performing the constant current-constant voltage charge at a current of 7×I20 A and a voltage of 14.4 V for 2400 seconds, and further performing the constant current discharge at a current of 7×I20 A for 1800 seconds.

(3) After the 85-cycle operations have ended, the constant current-constant voltage charge is performed at a current of 2×I20 A and a voltage of 16 V for 18 hours, further the constant current discharge is performed at a current of I20 A until the voltage of the lead acid battery becomes 10.5 V, and further the constant current-constant voltage charge is performed at a current of 5×I20 A and a voltage of 16 V for 24 hours.

These series of operations (1) to (3) were defined as one cycle, and the operations (1) to (3) were repeatedly performed in cycles while measuring the voltage of the lead acid battery for every 10 seconds. When the voltage of the lead acid battery became less than 10 V during the discharge in the cycle, it was determined that the lead acid battery had reached its life. The results are shown in Tables 16 to 19. The numerical values of the life shown in Tables 16 to 19 are the relative values given that the life of the lead acid battery of the conventional example is 100. When the life was greater than 100, it was determined that the PSOC life performance (the life in the partially charged state) was excellent.

When it was determined that the lead acid battery had reached its life in the evaluation of the battery life described above, the difference in specific gravity between upper and lower portions of the electrolyte was measured, and the state of the stratification was evaluated by its measured value. The measurement of the specific gravity was performed using an optical hydrometer (battery coolant tester) manufactured by MonotaRO Co., Ltd. The results are shown in Tables 16 to 19. The numerical values of the difference in specific gravity shown in Tables 16 to 19 are the relative values given that the difference in specific gravity of the lead acid battery of the conventional example is 100. It was determined that the smaller the difference in specific gravity, the more the stratification is suppressed.

Evaluation of Increase in Internal Resistance

After the initial charge was performed for the produced lead acid battery, aging was performed for 48 hours. Then, the internal resistance of the lead acid battery was measured. This internal resistance measured value was set as an “initial value”.

Subsequently, the constant voltage charge was performed for the lead acid battery in the fully charged state after the aging, and the internal resistance immediately after the end of the constant voltage charge was measured. This internal resistance measured value was set as a “value immediately after charge”. The conditions of the constant voltage charge were a maximum current of 100 A, a control voltage of 14.0 V, and a charge time of 10 minutes (this lead acid battery had a 5-hour rate capacity (rated capacity) of 32 Ah).

The lead acid battery was left still for an hour after the end of the constant voltage charge, and the internal resistance after being left still was measured. This internal resistance measured value was set as a “value after being left still”.

These results are shown in Tables 16 to 19. The increase rate of the internal resistance was calculated using the initial value, the value immediately after charge, and the value after being left still, of the internal resistance. The increase rate of the value immediately after charge to the initial value was calculated by ([value immediately after charge]−[initial value])/[initial value], and the increase rate of the value after being left still to the initial value was calculated by ([value after being left still]−[initial value])/[initial value].

When a condition A that the increase rate of the value immediately after charge to the initial value is equal to or less than 10%, and a condition B that the increase rate of the value after being left still to the initial value is equal to or less than 5% or that the increase rate of the value after being left still is a value that is lower by 4% or more than the increase rate of the value immediately after charge are both satisfied, it is determined that the increase in internal resistance is significantly suppressed, and a mark ∘ is given in Tables 16 to 19.

When only either one of the condition A and the condition B is satisfied, it is determined that while the increase in internal resistance is sufficiently suppressed, it cannot be said to be significantly suppressed, and a mark Δ is given in Tables 16 to 19. When neither of the condition A nor the condition B is satisfied, it is determined that the suppression of the increase in internal resistance is slightly insufficient or totally insufficient, and a mark × is given in Tables 16 to 19.

Further, the numerical value (relative value) of the difference in specific gravity of the electrolyte and the determination result of the increase rate of the internal resistance were synthesized to make a total determination. In Tables 16 to 19, when the difference in specific gravity of the electrolyte is equal to or less than 90 and the determination result of the increase rate of the internal resistance is O or Δ, a mark ∘ is given, and a mark × is given in the other cases.

TABLE 16

| | | | | | | | | | | | Internal resistance | | | |
|---|---|---|---|---|---|---|---|---|---|---|---|---|---|---|
| | | | | | | | | | | | increase rate (%) | | | |
| | Varia- | Density | | | | | | | | | Increase | Increase | | |
| | tion | of | | | Charge | | Strati- | Internal resistance (mΩ) | | | rate of | rate of | Deter- | |
| | in | positive | Thick | | accept- | | fication | | Value | Value | value | value | mination | Total |
| | thick- | active | coating | Flat- | ance | Bat- | of | | imme- | after | imme- | after | on | deter- |
| | ness | material | degree | ness | perfor- | tery | elec- | Initial | diately | being | diately | being | internal | mina- |
| | (μm) | (g/cm³) | ratio | (mm) | mance | life | trolyte | value | after charge | left still | after charge | left still | resistance | tion |
| Conventional | 30 | 4.6 | 0.50 | 4.7 | 100 | 100 | 104 | 5.8 | 6.5 | 6.4 | 13 | 11 | × | × |
| Example | | | | | | | | | | | | | | |
| Comparative | | 4.3 | 0.50 | 4.6 | 100 | 95 | 104 | 5.7 | 6.4 | 6.4 | 13 | 13 | × | × |
| Example 1001 | | | | | | | | | | | | | | |
| Example 1001 | | | 0.67 | 2.1 | 101 | 101 | 83 | 5.3 | 5.7 | 5.6 | 7 | 6 | Δ | ○ |
| Example 1002 | | | 1.00 | 0.7 | 101 | 101 | 73 | 5.3 | 5.6 | 5.5 | 6 | 4 | ○ | ○ |
| Example 1003 | | | 1.33 | 2.0 | 101 | 101 | 82 | 5.4 | 5.8 | 5.6 | 7 | 4 | ○ | ○ |
| Comparative | | | 1.50 | 4.4 | 100 | 95 | 103 | 5.6 | 6.2 | 6.2 | 11 | 11 | × | × |
| Example 1002 | | | | | | | | | | | | | | |
| Comparative | | 4.4 | 0.50 | 4.5 | 100 | 96 | 103 | 5.6 | 6.3 | 6.2 | 13 | 11 | × | × |
| Example 1003 | | | | | | | | | | | | | | |
| Example 1004 | | | 0.67 | 2.0 | 101 | 102 | 82 | 5.5 | 5.9 | 5.8 | 7 | 6 | Δ | ○ |
| Example 1005 | | | 1.00 | 0.5 | 101 | 102 | 73 | 5.3 | 5.6 | 5.4 | 6 | 2 | ○ | ○ |
| Example 1006 | | | 1.33 | 2.0 | 101 | 102 | 83 | 5.4 | 5.8 | 5.7 | 7 | 6 | Δ | ○ |
| Comparative | | | 1.50 | 4.5 | 100 | 96 | 102 | 5.6 | 6.3 | 6.2 | 13 | 11 | × | × |
| Example 1004 | | | | | | | | | | | | | | |
| Comparative | | 4.5 | 0.50 | 4.5 | 100 | 97 | 103 | 5.5 | 6.1 | 6.0 | 13 | 11 | × | × |
| Example 1005 | | | | | | | | | | | | | | |
| Example 1007 | | | 0.67 | 2.2 | 101 | 102 | 82 | 5.5 | 5.8 | 5.7 | 5 | 4 | ○ | ○ |
| Example 1008 | | | 1.00 | 0.6 | 101 | 102 | 71 | 5.3 | 5.6 | 5.5 | 6 | 4 | ○ | ○ |
| Example 1009 | | | 1.33 | 2.1 | 101 | 102 | 84 | 5.5 | 6.0 | 5.8 | 7 | 6 | Δ | ○ |
| Comparative | | | 1.50 | 4.6 | 100 | 97 | 104 | 5.6 | 6.2 | 6.1 | 11 | 9 | × | × |
| Example 1006 | | | | | | | | | | | | | | |
| Example 1010 | | 4.6 | 0.67 | 2.3 | 101 | 102 | 81 | 5.5 | 5.9 | 5.8 | 7 | 6 | Δ | ○ |
| Example 1011 | | | 1.00 | 0.5 | 101 | 102 | 73 | 5.4 | 5.7 | 5.5 | 6 | 2 | ○ | ○ |
| Example 1012 | | | 1.33 | 2.5 | 101 | 102 | 83 | 5.4 | 5.7 | 5.6 | 7 | 6 | Δ | ○ |
| Comparative | | | 1.50 | 4.7 | 100 | 100 | 103 | 5.6 | 6.2 | 6.1 | 11 | 9 | × | × |
| Example 1007 | | | | | | | | | | | | | | |
| Comparative | | 4.7 | 0.50 | 4.6 | 101 | 98 | 102 | 5.5 | 6.1 | 6.0 | 12 | 11 | × | × |
| Example 1008 | | | | | | | | | | | | | | |
| Example 1013 | | | 0.67 | 2.7 | 102 | 101 | 82 | 5.4 | 5.8 | 5.7 | 7 | 6 | Δ | ○ |
| Example 1014 | | | 1.00 | 0.5 | 102 | 101 | 73 | 5.5 | 5.8 | 5.6 | 6 | 2 | ○ | ○ |
| Example 1015 | | | 1.33 | 2.7 | 102 | 101 | 82 | 5.3 | 5.7 | 5.6 | 7 | 6 | Δ | ○ |
| Comparative | | | 1.50 | 5.1 | 101 | 98 | 103 | 5.9 | 6.7 | 6.7 | 14 | 14 | × | × |
| Example 1009 | | | | | | | | | | | | | | |

TABLE 17

| | | | | | | | | | | | Internal resistance | | | |
|---|---|---|---|---|---|---|---|---|---|---|---|---|---|---|
| | | | | | | | | | | | increase rate (%) | | | |
| | Varia- | Density | | | | | | | | | Increase | Increase | | |
| | tion | of | | | Charge | | Strati- | Internal resistance (mΩ) | | | rate of | rate of | Deter- | |
| | in | positive | Thick | | accept- | | fication | | Value | Value | value | value | mination | Total |
| | thick- | active | coating | Flat- | ance | Bat- | of | | imme- | after | imme- | after | on | deter- |
| | ness | material | degree | ness | perfor- | tery | elec- | Initial | diately | being | diately | being | internal | mina- |
| | (μm) | (g/cm³) | ratio | (mm) | mance | life | trolyte | value | after charge | left still | after charge | left still | resistance | tion |
| Comparative | 50 | 4.3 | 0.50 | 4.4 | 99 | 94 | 105 | 5.5 | 6.1 | 6.1 | 13 | 13 | × | × |
| Example 1010 | | | | | | | | | | | | | | |
| Example 1016 | | | 0.67 | 2.2 | 100 | 100 | 83 | 5.5 | 6.0 | 5.9 | 7 | 6 | Δ | ○ |
| Example 1017 | | | 1.00 | 0.7 | 100 | 100 | 74 | 5.6 | 5.9 | 5.8 | 6 | 4 | ○ | ○ |
| Example 1018 | | | 1.33 | 2.0 | 100 | 100 | 82 | 5.5 | 5.9 | 5.7 | 7 | 4 | ○ | ○ |
| Comparative | | | 1.50 | 4.5 | 99 | 94 | 104 | 5.7 | 6.3 | 6.3 | 11 | 11 | × | × |
| Example 1011 | | | | | | | | | | | | | | |
| Comparative | | 4.4 | 0.50 | 4.6 | 99 | 95 | 104 | 5.7 | 6.4 | 6.3 | 13 | 11 | × | × |
| Example 1012 | | | | | | | | | | | | | | |
| Example 1019 | | | 0.67 | 2.0 | 100 | 101 | 82 | 5.3 | 5.7 | 5.6 | 7 | 6 | Δ | ○ |
| Example 1020 | | | 1.00 | 0.5 | 100 | 101 | 74 | 5.2 | 5.5 | 5.3 | 6 | 2 | ○ | ○ |
| Example 1021 | | | 1.33 | 2.0 | 100 | 101 | 83 | 5.5 | 5.9 | 5.8 | 7 | 6 | Δ | ○ |
| Comparative | | | 1.50 | 4.5 | 99 | 95 | 103 | 5.6 | 6.3 | 6.2 | 13 | 11 | × | × |
| Example 1013 | | | | | | | | | | | | | | |
| Comparative | | 4.5 | 0.50 | 4.6 | 99 | 96 | 104 | 5.6 | 6.3 | 6.2 | 13 | 11 | × | × |
| Example 1014 | | | | | | | | | | | | | | |
| Example 1022 | | | 0.67 | 2.3 | 100 | 101 | 82 | 5.7 | 6.0 | 5.9 | 5 | 4 | ○ | ○ |
| Example 1023 | | | 1.00 | 0.6 | 100 | 101 | 72 | 5.4 | 5.7 | 5.6 | 6 | 4 | ○ | ○ |
| Example 1024 | | | 1.33 | 2.1 | 100 | 101 | 84 | 5.6 | 6.0 | 5.9 | 7 | 6 | Δ | ○ |
| Comparative | | | 1.50 | 4.6 | 99 | 96 | 105 | 5.6 | 6.2 | 6.1 | 11 | 9 | × | × |
| Example 1015 | | | | | | | | | | | | | | |
| Comparative | | 4. 6 | 0.50 | 4.7 | 99 | 96 | 105 | 5.8 | 6.5 | 6.4 | 13 | 11 | × | × |
| Example 1016 | | | | | | | | | | | | | | |
| Example 1025 | | | 0.67 | 2.3 | 100 | 101 | 81 | 5.4 | 5.8 | 5.7 | 7 | 6 | Δ | ○ |
| Example 1026 | | | 1.00 | 0.5 | 100 | 101 | 74 | 5.5 | 5.8 | 5.6 | 6 | 2 | ○ | ○ |
| Example 1027 | | | 1.33 | 2.4 | 100 | 101 | 83 | 5.3 | 5.7 | 5.6 | 7 | 6 | Δ | ○ |
| Comparative | | | | | | | | | | | | | | |
| Example 1017 | | | 1.50 | 4.9 | 99 | 96 | 104 | 5.8 | 6.4 | 6.3 | 11 | 9 | × | × |
| Comparative | | 4.7 | 0.50 | 4.9 | 100 | 97 | 103 | 5.8 | 6.5 | 6.4 | 12 | 11 | × | × |
| Example 1018 | | | | | | | | | | | | | | |
| Example 1028 | | | 0.67 | 2.7 | 101 | 100 | 82 | 5.3 | 5.7 | 5.6 | 7 | 6 | Δ | ○ |
| Example 1029 | | | 1.00 | 0.5 | 101 | 100 | 74 | 5.2 | 5.5 | 5.3 | 6 | 2 | ○ | ○ |
| Example 1030 | | | 1.33 | 2.7 | 101 | 100 | 82 | 5.5 | 5.9 | 5.8 | 7 | 6 | Δ | ○ |
| Comparative | | | | | | | | | | | | | | |
| Example 1019 | | | 1.50 | 5.0 | 100 | 97 | 104 | 5.7 | 6.5 | 6.5 | 14 | 14 | × | × |

TABLE 18

| | | | | | | | | | | | Internal resistance | | | |
|---|---|---|---|---|---|---|---|---|---|---|---|---|---|---|
| | | | | | | | | | | | increase rate (%) | | | |
| | Varia- | Density | | | | | | | | | Increase | Increase | | |
| | tion | of | | | Charge | | Strati- | Internal resistance (mΩ) | | | rate of | rate of | Deter- | |
| | in | positive | Thick | | accept- | | fication | | Value | Value | value | value | mination | Total |
| | thick- | active | coating | Flat- | ance | Bat- | of | | imme- | after | imme- | after | on | deter- |
| | ness | material | degree | ness | perfor- | tery | elec- | Initial | diately | being | diately | being | internal | mina- |
| | (μm) | (g/cm³) | ratio | (mm) | mance | life | trolyte | value | after charge | left still | after charge | left still | resistance | tion |
| Comparative | 15 | 4.3 | 0.50 | 4.5 | 101 | 96 | 103 | 5.6 | 6.4 | 6.4 | 13 | 13 | × | × |
| Example 1020 | | | | | | | | | | | | | | |
| Example 1031 | | | 0.67 | 2.1 | 102 | 102 | 82 | 5.4 | 5.8 | 5.7 | 7 | 6 | Δ | ○ |
| Example 1032 | | | 1.00 | 0.7 | 102 | 102 | 73 | 5.4 | 5.8 | 5.6 | 6 | 4 | ○ | ○ |
| Example 1033 | | | 1.33 | 2.0 | 102 | 102 | 81 | 5.5 | 5.9 | 5.7 | 7 | 4 | ○ | ○ |
| Comparative | | | 1.50 | 4.5 | 101 | 96 | 102 | 5.8 | 6.4 | 6.4 | 11 | 11 | × | × |
| Example 1021 | | | | | | | | | | | | | | |
| Comparative | | 4.4 | 0.50 | 4.6 | 101 | 97 | 102 | 5.7 | 6.4 | 6.3 | 13 | 11 | × | × |
| Example 1022 | | | | | | | | | | | | | | |
| Example 1034 | | | 0.67 | 2.0 | 102 | 103 | 81 | 5.5 | 5.9 | 5.8 | 7 | 6 | Δ | ○ |
| Example 1035 | | | 1.00 | 0.5 | 102 | 103 | 73 | 5.4 | 5.7 | 5.5 | 6 | 2 | ○ | ○ |
| Example 1036 | | | 1.33 | 2.0 | 102 | 103 | 82 | 5.5 | 5.9 | 5.8 | 7 | 6 | Δ | ○ |
| Comparative | | | 1.50 | 4.5 | 101 | 97 | 101 | 5.5 | 6.2 | 6.1 | 13 | 11 | × | × |
| Example 1023 | | | | | | | | | | | | | | |
| Comparative | | 4.5 | 0.50 | 4.7 | 101 | 98 | 102 | 5.7 | 6.4 | 6.3 | 13 | 11 | × | × |
| Example 1024 | | | | | | | | | | | | | | |
| Example 1037 | | | 0.67 | 2.2 | 102 | 103 | 81 | 5.6 | 5.9 | 5.8 | 5 | 4 | ○ | ○ |
| Example 1038 | | | 1.00 | 0.6 | 102 | 103 | 71 | 5.2 | 5.5 | 5.4 | 6 | 4 | ○ | ○ |
| Example 1039 | | | 1.33 | 2.0 | 102 | 103 | 83 | 5.5 | 5.9 | 5.8 | 7 | 6 | Δ | ○ |
| Comparative | | | 1.50 | 4.8 | 101 | 98 | 103 | 5.8 | 6.4 | 6.3 | 11 | 9 | × | × |
| Example 1025 | | | | | | | | | | | | | | |
| Comparative | | 4.6 | 0.50 | 4.6 | 101 | 98 | 103 | 5.7 | 6.4 | 6.3 | 13 | 11 | × | × |
| Example 1026 | | | | | | | | | | | | | | |
| Example 1040 | | | 0.67 | 2.3 | 102 | 103 | 80 | 5.4 | 5.8 | 5.7 | 7 | 6 | Δ | ○ |
| Example 1041 | | | 1.00 | 0.5 | 102 | 103 | 73 | 5.3 | 5.6 | 5.4 | 6 | 2 | ○ | ○ |
| Example 1042 | | | 1.33 | 2.4 | 102 | 103 | 82 | 5.3 | 5.7 | 5.6 | 7 | 6 | Δ | ○ |
| Comparative | | | 1.50 | 4.7 | 101 | 98 | 102 | 5.6 | 6.2 | 6.1 | 11 | 9 | × | × |
| Example 1027 | | | | | | | | | | | | | | |
| Comparative | | 4.7 | 0.50 | 4.8 | 102 | 99 | 101 | 5.7 | 6.4 | 6.3 | 12 | 11 | × | × |
| Example 1028 | | | | | | | | | | | | | | |
| Example 1043 | | | 0.67 | 2.6 | 103 | 102 | 81 | 5.2 | 5.6 | 5.5 | 7 | 6 | Δ | ○ |
| Example 1044 | | | 1.00 | 0.5 | 103 | 102 | 73 | 5.4 | 5.7 | 5.5 | 6 | 2 | ○ | ○ |
| Example 1045 | | | 1.33 | 2.8 | 103 | 102 | 81 | 5.5 | 5.9 | 5.8 | 7 | 6 | Δ | ○ |
| Comparative | | | 1.50 | 5.1 | 102 | 99 | 102 | 5.8 | 6.6 | 6.6 | 14 | 14 | × | × |
| Example 1029 | | | | | | | | | | | | | | |

TABLE 19

| | | | | | | | | | | | Internal resistance | | | |
|---|---|---|---|---|---|---|---|---|---|---|---|---|---|---|
| | | | | | | | | | | | increase rate (%) | | | |
| | Varia- | Density | | | | | | | | | Increase | Increase | | |
| | tion | of | | | Charge | | Strati- | Internal resistance (mΩ) | | | rate of | rate of | Deter- | |
| | in | positive | Thick | | accept- | | fication | | Value | Value | value | value | mination | Total |
| | thick- | active | coating | Flat- | ance | Bat- | of | | imme- | after | imme- | after | on | deter- |
| | ness | material | degree | ness | perfor- | tery | elec- | Initial | diately | being | diately | being | internal | mina- |
| | (μm) | (g/cm³) | ratio | (mm) | mance | life | trolyte | value | after charge | left still | after charge | left still | resistance | tion |
| Comparative | 10 | 4.3 | 0.50 | 4.5 | 101 | 96 | 102 | 5.6 | 6.3 | 6.3 | 13 | 13 | × | × |
| Example 1030 | | | | | | | | | | | | | | |
| Example 1046 | | | 0.67 | 2.1 | 102 | 102 | 81 | 5.4 | 5.8 | 5.7 | 7 | 6 | Δ | ○ |
| Example 1047 | | | 1.00 | 0.7 | 102 | 102 | 72 | 5.3 | 5.6 | 5.5 | 6 | 4 | ○ | ○ |
| Example 1048 | | | 1.33 | 2.0 | 102 | 102 | 80 | 5.4 | 5.8 | 5.6 | 7 | 4 | ○ | ○ |
| Comparative | | | 1.50 | 4.4 | 101 | 96 | 101 | 5.6 | 6.2 | 6.2 | 11 | 11 | × | × |
| Example 1031 | | | | | | | | | | | | | | |
| Comparative | | 4.4 | 0.50 | 4.5 | 101 | 97 | 101 | 5.6 | 6.3 | 6.2 | 13 | 11 | × | × |
| Example 1032 | | | | | | | | | | | | | | |
| Example 1049 | | | 0.67 | 2.0 | 102 | 103 | 80 | 5.4 | 5.8 | 5.7 | 7 | 6 | Δ | ○ |
| Example 1050 | | | 1.00 | 0.5 | 102 | 103 | 72 | 5.3 | 5.6 | 5.4 | 6 | 2 | ○ | ○ |
| Example 1051 | | | 1.33 | 2.0 | 102 | 103 | 81 | 5.4 | 5.8 | 5.7 | 7 | 6 | Δ | ○ |
| Comparative | | | 1.50 | 4.5 | 101 | 97 | 100 | 5.6 | 6.3 | 6.2 | 13 | 11 | × | × |
| Example 1033 | | | | | | | | | | | | | | |
| Comparative | | 4.5 | 0.50 | 4.6 | 101 | 98 | 101 | 5.6 | 6.3 | 6.2 | 13 | 11 | × | × |
| Example 1034 | | | | | | | | | | | | | | |
| Example 1052 | | | 0.67 | 2.2 | 102 | 103 | 80 | 5.5 | 5.8 | 5.7 | 5 | 4 | ○ | ○ |
| Example 1053 | | | 1.00 | 0.6 | 102 | 103 | 70 | 5.3 | 5.6 | 5.5 | 6 | 4 | ○ | ○ |
| Example 1054 | | | 1.33 | 2.0 | 102 | 103 | 82 | 5.4 | 5.8 | 5.7 | 7 | 6 | Δ | ○ |
| Comparative | | | 1.50 | 4.7 | 101 | 98 | 102 | 5.7 | 6.3 | 6.2 | 11 | 9 | × | × |
| Example 1035 | | | | | | | | | | | | | | |
| Comparative | | 4.6 | 0.50 | 4.6 | 101 | 98 | 102 | 5.6 | 6.3 | 6.2 | 13 | 11 | × | × |
| Example 1036 | | | | | | | | | | | | | | |
| Example 1055 | | | 0.67 | 2.3 | 102 | 103 | 79 | 5.4 | 5.8 | 5.7 | 7 | 6 | Δ | ○ |
| Example 1056 | | | 1.00 | 0.5 | 102 | 103 | 72 | 5.3 | 5.6 | 5.4 | 6 | 2 | ○ | ○ |
| Example 1057 | | | 1.33 | 2.5 | 102 | 103 | 81 | 5.4 | 5.8 | 5.7 | 7 | 6 | Δ | ○ |
| Comparative | | | 1.50 | 4.8 | 101 | 98 | 101 | 5.7 | 6.3 | 6.2 | 11 | 9 | × | × |
| Example 1037 | | | | | | | | | | | | | | |
| Comparative | | 4.7 | 0.50 | 4.8 | 102 | 99 | 100 | 5.7 | 6.4 | 6.3 | 12 | 11 | × | × |
| Example 1038 | | | | | | | | | | | | | | |
| Example 1058 | | | 0.67 | 2.7 | 103 | 102 | 80 | 5.4 | 5.8 | 5.7 | 7 | 6 | Δ | ○ |
| Example 1059 | | | 1.00 | 0.5 | 103 | 102 | 72 | 5.3 | 5.6 | 5.4 | 6 | 2 | ○ | ○ |
| Example 1060 | | | 1.33 | 2.7 | 103 | 102 | 80 | 5.4 | 5.8 | 5.7 | 7 | 6 | Δ | ○ |
| Comparative | | | 1.50 | 5.0 | 102 | 99 | 101 | 5.7 | 6.5 | 6.5 | 14 | 14 | × | × |
| Example 1039 | | | | | | | | | | | | | | |

As seen from Tables 16 to 19, when the thick coating degree ratio B/A of the positive electrode plate was equal to or more than 0.67 and equal to or less than 1.33, since the numerical value of the flatness of the positive electrode plate was small (the curvature was small) compared to the case where the thick coating degree ratio B/A of the positive electrode plate was 0.50 or 1.50, there were a tendency that the stratification tended to be suppressed, and a tendency that the increase rate of the internal resistance was low. In particular, when the thick coating degree ratio B/A of the positive electrode plate was 1.00, the numerical value of the flatness of the positive electrode plate became smaller so that the stratification was more unlikely to occur and that the increase rate of the internal resistance was low. This is considered to be because gas produced on the positive electrode plate rises in the electrolyte to stir the electrolyte so that the stratification is suppressed.

Further, when the parameter R representing the degree of variation in the thickness of the positive electrode plate was small, there was observed a tendency that the charge acceptance performance was excellent. When the parameter R representing the degree of variation in the thickness of the positive electrode plate was 50 μm, there was a tendency that the charge acceptance performance and the PSOC life performance were low compared to the case where the parameter R was 10 μm, 15 μm, or 30 μm. This is presumed to be because cracks tend to occur in the positive electrode plate due to the presence of irregularities on the surface of the positive electrode plate. Accordingly, the charge acceptance performance and the PSOC life performance decrease by the influence thereof. Further, it is considered that the stratification also tends to occur due to the decrease in charge acceptance performance.

Further, when the density of the positive active material was equal to or more than 4.4 g/cm³ and equal to or less than 4.6 g/cm³, the PSOC life performance was excellent. When the density of the positive active material was 4.3 g/cm³ or 4.7 g/cm³, there was a tendency that the PSOC life performance decreased compared to the case where the density of the positive active material was equal to or more than 4.4 g/cm³ and equal to or less than 4.6 g/cm³.

A list of reference signs used in the drawing figures is shown below:
1 electrode plate group
10 positive electrode plate
20 negative electrode plate
30 separator

1.-11. (canceled)

12. A lead acid battery comprising an electrode plate group in which a plurality of positive electrode plates having a positive active material containing lead dioxide and a plurality of negative electrode plates having a negative active material containing metallic lead are alternately stacked with separators interposed between the positive electrode plates and the negative electrode plates, wherein the electrode plate group is immersed in an electrolyte, and a flatness of the positive electrode plate after chemical conversion is equal to or less than 4.0 mm, and
wherein an average diameter of pores included in the positive active material is equal to or more than 0.07 μm and equal to or less than 0.20 μm, and a porosity of the positive active material is equal to or more than 30% and equal to or less than 50%.

13. A lead acid battery comprising an electrode plate group in which a plurality of positive electrode plates having a positive active material containing lead dioxide and a plurality of negative electrode plates having a negative active material containing metallic lead are alternately stacked with separators interposed between the positive electrode plates and the negative electrode plates, wherein the electrode plate group is immersed in an electrolyte, and a flatness of the positive electrode plate after chemical conversion is equal to or less than 4.0 mm, and
wherein the positive electrode plate after the chemical conversion is curved in a generally bowl shape, and an apex of a convex surface of the positive electrode plate curved is located at a portion below a center of the positive electrode plate in a vertical direction.

14. A lead acid battery comprising an electrode plate group in which a plurality of positive electrode plates having a positive active material containing lead dioxide and a plurality of negative electrode plates having a negative active material containing metallic lead are alternately stacked with separators interposed between the positive electrode plates and the negative electrode plates, wherein the electrode plate group is immersed in an electrolyte, and a flatness of the positive electrode plate after chemical conversion is equal to or less than 4.0 mm, and wherein a ratio α/(α+β) between a mass α of α-lead dioxide and a mass β of β-lead dioxide contained in the positive active material is equal to or more than 20% and equal to or less than 40%.

15. A lead acid battery comprising an electrode plate group in which a plurality of positive electrode plates having a positive active material containing lead dioxide and a plurality of negative electrode plates having a negative active material containing metallic lead are alternately stacked with separators interposed between the positive electrode plates and the negative electrode plates, wherein the electrode plate group is immersed in an electrolyte, and a flatness of the positive electrode plate after chemical conversion is equal to or less than 4.0 mm,
wherein the negative electrode plate includes a plate-like grid formed with an opening, the negative electrode plate produced such that while filling the negative active material in the opening of the plate-like grid, an active material layer made of the negative active material is formed on both plate surfaces of the plate-like grid, and
wherein distances between the positive electrode plate and the negative electrode plate adjacent to each other are all equal to or more than 0.60 mm and equal to or less than 0.90 mm

16. A lead acid battery comprising an electrode plate group in which a plurality of positive electrode plates having a positive active material containing lead dioxide and a plurality of negative electrode plates having a negative active material containing metallic lead are alternately stacked with separators interposed between the positive electrode plates and the negative electrode plates, wherein the electrode plate group is immersed in an electrolyte, and a flatness of the positive electrode plate after chemical conversion is equal to or less than 4.0 mm,
wherein a content of iron contained in the positive active material in a fully charged state is equal to or more than 3.5 ppm and equal to or less than 20.0 ppm, and wherein the positive electrode plate after the chemical conversion is curved in a generally bowl shape, and an apex of a convex surface of the positive electrode plate curved is located at a portion below a center of the positive electrode plate in a vertical direction.

17. A lead acid battery used in a partially charged state and comprising an electrode plate group in which a plurality of positive electrode plates having a positive active material containing lead dioxide and a plurality of negative electrode plates having a negative active material containing metallic lead are alternately stacked with separators interposed between the positive electrode plates and the negative electrode plates, wherein the electrode plate group is immersed in an electrolyte, and a flatness of the positive electrode plate after chemical conversion is equal to or less than 4.0 mm,
wherein the positive electrode plate after the chemical conversion is configured such that positive active material layers made of the positive active material are respectively disposed on both plate surfaces of a positive electrode substrate, and that a ratio of a thickness of the positive active material layer on one of the plate surfaces of the positive electrode substrate to a thickness of the positive active material layer on the other one of the plate surfaces of the positive electrode substrate is equal to or more than 0.67 and equal to or less than 1.33, and
wherein the positive electrode plate after the chemical conversion is curved in a generally bowl shape, and an apex of a convex surface of the positive electrode plate curved is located at a portion below a center of the positive electrode plate in a vertical direction.

18. The lead acid battery according to claim 12, wherein a density of the positive active material is equal to or more than 4.2 g/cm³ and equal to or less than 4.6 g/cm³.

19. The lead acid battery according to claim 12, wherein a content of aluminum ions in the electrolyte is equal to or more than 0.01 mol/L and equal to or less than 0.3 mol/L.

20. The lead acid battery according to claim 12, wherein a group pressure applied to the electrode plate group is equal to or less than 10 kPa.

21. The lead acid battery according to claim 13, wherein a density of the positive active material is equal to or more than 4.2 g/cm³ and equal to or less than 4.6 g/cm³.

22. The lead acid battery according to claim 14, wherein a density of the positive active material is equal to or more than 4.2 g/cm³ and equal to or less than 4.6 g/cm³.

23. The lead acid battery according to claim 15, wherein a density of the positive active material is equal to or more than 4.2 g/cm³ and equal to or less than 4.6 g/cm³.

24. The lead acid battery according to claim 16, wherein a density of the positive active material is equal to or more than 4.2 g/cm³ and equal to or less than 4.6 g/cm³.

25. The lead acid battery according to claim 17, wherein a density of the positive active material is equal to or more than 4.2 g/cm³ and equal to or less than 4.6 g/cm³.

26. The lead acid battery according to claim 13, wherein a content of aluminum ions in the electrolyte is equal to or more than 0.01 mol/L and equal to or less than 0.3 mol/L.

27. The lead acid battery according to claim 14, wherein a content of aluminum ions in the electrolyte is equal to or more than 0.01 mol/L and equal to or less than 0.3 mol/L.

28. The lead acid battery according to claim 15, wherein a content of aluminum ions in the electrolyte is equal to or more than 0.01 mol/L and equal to or less than 0.3 mol/L.

29. The lead acid battery according to claim 16, wherein a content of aluminum ions in the electrolyte is equal to or more than 0.01 mol/L and equal to or less than 0.3 mol/L.

30. The lead acid battery according to claim 17, wherein a content of aluminum ions in the electrolyte is equal to or more than 0.01 mol/L and equal to or less than 0.3 mol/L.

31. The lead acid battery according to claim 18, wherein a content of aluminum ions in the electrolyte is equal to or more than 0.01 mol/L and equal to or less than 0.3 mol/L.
